(19) United States
(12) Patent Application Publication
(10) Pub. No.: US 2025/0253827 A1
(43) Pub. Date: Aug. 7, 2025

(54) HIGH PASS FILTER AND ACOUSTIC DEVICE INCLUDING THE SAME

(71) Applicant: SAMSUNG ELECTRONICS CO., LTD., SUWON-SI (KR)

(72) Inventors: BYUNGGYU LEE, SUWON-SI (KR); INHWAN CHO, SUWON-SI (KR)

(21) Appl. No.: 19/037,558

(22) Filed: Jan. 27, 2025

(30) Foreign Application Priority Data
Feb. 2, 2024 (KR) 10-2024-0016904
Jul. 5, 2024 (KR) 10-2024 0089146

(51) Int. Cl. H03H 9/54; H03H 7/06

(52) U.S. Cl. CPC H03H 9/542; H03H 7/06

(57) ABSTRACT

A high pass filter includes a first stage circuit, a second stage circuit and a third stage circuit. The first stage circuit includes an attenuating circuit configured to receive an amplifier feedback output signal applied from a node connected to an output terminal of the amplifier and to a filter capacitor, and output an attenuated signal by attenuating a voltage level of the amplifier feedback output signal. The second stage circuit is configured to receive the attenuated signal and perform a low filtering operation on the attenuated signal to output a low filter output signal. The third stage circuit is configured to receive the low filter output signal and perform a cross sampling operation on the low filter output signal to output a feedback input signal to a node connected to an input terminal of the amplifier and to the filter capacitor.

### CROSS-REFERENCE TO RELATED APPLICATION

This patent application claims priority under 35 U.S.C. § 119 to Korean Patent Application Nos. 10-2024-0016904, filed on Feb. 2, 2024, and 2024-0089146, filed on Jul. 5, 2024, in the Korean Intellectual Property Office, the disclosures of which are incorporated by reference in their entireties herein.

### 1. TECHNICAL FIELD

The inventive concept is directed to a high pass filter, and more particularly, to a high pass filter in an acoustic device.

### 2. DISCUSSION OF RELATED ART

A high pass filter may be used in an acoustic device such as a speaker to block low-frequency components. A capacitive programmable gain amplifier (PGA) may be configured to perform the function of the high pass filter. The PGA requires a resistor between the amplifier output and input to control direct current (DC) bias of the amplifier input. A resistor with a configurable resistance can be used to prevent its noise from folding into the signal band.

Examples of elements that provide configurable resistance include a pseudo resistor, a duty-cycled resistor, and a resistor ladder. The pseudo resistor requires linearity, controllability, and resistance to process-voltage-temperature (PVT) variation. The duty-cycled resistor requires a very short duty cycle to achieve a high effective resistance. However, any mismatch in the duty cycle introduces an offset at the output, which can reduce the dynamic range of the system.

The resistor ladder can be used to generate different resistances by leveraging the combination of resistor values in the ladder network. The resistor ladder is less susceptible to PVT variations and has better linearity and controllability compared to a pseudo resistor. However, the resistor ladder may introduce an unintended DC offset that degrades performance of the acoustic device.

Thus, there is a need for a high pass filter for use in an acoustic device without degrading performance of the acoustic device.

### SUMMARY

The inventive concept provides a high pass filter with increased performance.

According to an aspect of the inventive concept, there is provided a high pass filter including an amplifier including an input terminal and an output terminal, a filter capacitor connected between the input terminal and the output terminal, and a resistance circuit connected between the input terminal and the output terminal. The resistance circuit includes a first stage circuit including an attenuating circuit configured to receive an amplifier feedback output signal applied from a node connected to the output terminal of the amplifier and to the filter capacitor, and output an attenuated signal by attenuating a voltage level of the amplifier feedback output signal, a second stage circuit configured to receive the attenuated signal and perform a low filtering operation on the attenuated signal to output a low filter output signal, and a third stage circuit configured to receive the low filter output signal and perform a cross sampling circuit operation on the low filter output signal to output a feedback input signal to a node connected to the input terminal of the amplifier and to the filter capacitor.

According to an embodiment of the inventive concept, there is provided an acoustic device including a high pass filter including an amplifier having an input terminal and an output terminal, a filter capacitor connected between the input terminal and the output terminal, and a resistance circuit connected between the input terminal and the output terminal. The resistance circuit includes a first stage circuit including an attenuating circuit configured to receive an amplifier feedback output signal applied from a node connected to the output terminal of the amplifier and to the filter capacitor, and output an attenuated signal by attenuating a voltage level of the amplifier feedback output signal, a second stage circuit configured to receive the attenuated signal and perform a low filtering operation on the attenuated signal to output a low filter output signal, and a third stage circuit configured to receive the low filter output signal and perform a cross sampling operation on the low filter output signal to output a feedback input signal to a node connected to the input terminal of the amplifier and to the filter capacitor.

According to an embodiment of the inventive concept, there is provided a high pass filter including an amplifier having an input terminal including a non-inverting input terminal and an inverting input terminal, and an output terminal including an inverting output terminal and a non-inverting output terminal, a filter capacitor and a resistance circuit. The filter capacitor is connected between the input terminal and the output terminal. The resistance circuit is connected between the input terminal and the output terminal. The resistance circuit includes a first resistor connected between a node connecting the filter capacitor to the inverting output terminal, and a second node, a second resistor connected between a first node connected to an output common mode signal line, and the second node, a third resistor connected between a node connecting the filter capacitor to the non-inverting output terminal, and a fourth node, a fourth resistor connected between the first node and the fourth node, a first operational amplifier connected between the second node and the third node, a non-inverting input terminal of the first operational amplifier being connected to the second node, and an inverting input terminal of the first operational amplifier being connected to an output terminal of the first operational amplifier at the third node, a second operational amplifier connected between the fourth node and the fifth node, a non-inverting input terminal of the second operational amplifier being connected to the fourth node, and an inverting input terminal of the second operational amplifier being connected to an output terminal of the second operational amplifier at the fifth node, a first switch connected between the third node and the sixth node, a first capacitor connected between the sixth node and a ground voltage line, a second switch connected between the sixth node and a seventh node, a third switch connected between the seventh node and an eighth node, a second capacitor connected between the eighth node and the ground voltage line, a fourth switch connected between the eighth node and a ninth node, a fifth switch connected between the fifth node and a tenth node, a third capacitor connected between the tenth node and the ground voltage line, a sixth switch connected between the tenth node and an eleventh node, a seventh switch connected between the eleventh node and a twelfth node, a fourth capacitor connected between the twelfth node and the ground voltage line, an eighth switch connected between the twelfth node and a thirteenth node, a fifth capacitor connected between the seventh node and the eleventh node, a sixth capacitor connected between the ninth node and the thirteenth node, a ninth switch connected between the ninth node and a fourteenth node, a seventh capacitor connected between the fourteenth node and the ground voltage line, a tenth switch connected between a node connecting the filter capacitor to the non-inverting input terminal, and the fourteenth node, an eleventh switch connected between the thirteenth node and a fifteenth node, an eighth capacitor connected between the fifteenth node and the ground voltage line, a twelfth switch connected between a node connecting the filter capacitor to the inverting input terminal, and the fifteenth node, a thirteenth switch connected between the ninth node and the fifteenth node, a fourteenth switch connected between the thirteenth node and the fourteenth node, a fifteenth switch connected between a node connecting the filter capacitor to the non-inverting input terminal, and the fifteenth node, a sixteenth switch connected between a node connecting the filter capacitor to the inverting input terminal, and the fourteenth node, and a ninth capacitor connected between the fourteenth node and the fifteenth node.

### BRIEF DESCRIPTION OF THE DRAWINGS

Embodiments will be more clearly understood from the following detailed description taken in conjunction with the accompanying drawings in which:

FIG. 1 is a diagram illustrating a high pass filter according to an embodiment;

FIG. 2 is a diagram illustrating a resistance circuit according to an embodiment;

FIG. 3 is a diagram illustrating a first stage circuit according to an embodiment;

FIG. 4 is a diagram showing an equivalent circuit of a first stage circuit according to an embodiment;

FIG. 5 is a diagram illustrating a second stage circuit according to an embodiment;

FIG. 6 is a diagram to explain a switched capacitor circuit;

FIG. 7 is a diagram showing an equivalent circuit of a second stage circuit according to an embodiment;

FIG. 8 is a diagram illustrating a third stage circuit according to an embodiment;

FIG. 9 is a diagram showing an equivalent circuit of a third stage circuit according to an embodiment;

FIG. 10 is a timing diagram showing sample clock signals SCLK1 and SLCK2 and sample clock pulse signals SCLK1_pls and SCLK2_pls;

FIG. 11 is a diagram showing an operation of a cross sampling circuit of a 1^{st}-1 phase;

FIG. 12 is a diagram showing an operation of a cross sampling circuit of a 1^{st}-2 phase;

FIG. 13 is a diagram showing an operation of a cross sampling circuit of a 2^{nd}-1 phase;

FIG. 14 is a diagram showing an operation of a cross sampling circuit of a 2^{nd}-2 phase;

FIG. 15 is a diagram showing an equivalent circuit of a resistance circuit according to an embodiment; and

FIG. 16 is a block diagram illustrating an apparatus according to an embodiment.

### DETAILED DESCRIPTION OF THE EMBODIMENTS

Hereinafter, various embodiments are described with reference to the attached drawings.

At least one of the embodiments pertains to a high-pass filter integrated into an acoustic device, designed to efficiently pass higher frequency components while attenuating lower ones. The inclusion of a multistage resistance circuit (e.g., an attenuation stage, a low-pass filtering stage and a cross-sampling stage) in the high-pass filter may ensure high performance, reduce DC offset, and increase area efficiency on integrated circuits. By leveraging shared and switched capacitors, the system may enhance the effective resistance without increasing physical size, achieving precise frequency control and adaptability.

The attenuation stage may use a resistor ladder or equivalent circuitry to attenuate the amplifier feedback output signal. This reduces the signal level to a manageable range for subsequent stages. This may ensure that high signal levels are scaled down for precise processing, reduce the load on the downstream components for enhancing overall system stability, and facilitate resistance adjustment dynamically to cater to different acoustic device requirements.

The low-pass filtering stage may perform low-pass filtering on the attenuated signal using switched capacitor circuits and shared capacitors to emulate high resistance and filter out high-frequency noise. This stage may smooth the signal by removing unwanted high-frequency components, reduce the impact of noise and DC offset introduced by the resistor ladder, and enhance area efficiency by using shared capacitors between resistance paths for saving physical space on integrated circuits.

The cross-sampling stage may average mismatches between resistance paths and parasitic capacitances by alternating sampling paths and redistributing mismatched effects across cycles. This stage may reduce unintended DC offsets caused by resistance path mismatches. compensate for parasitic capacitance for ensuring accurate signal reproduction, and increase reliability and quality of the output signal for the acoustic device.

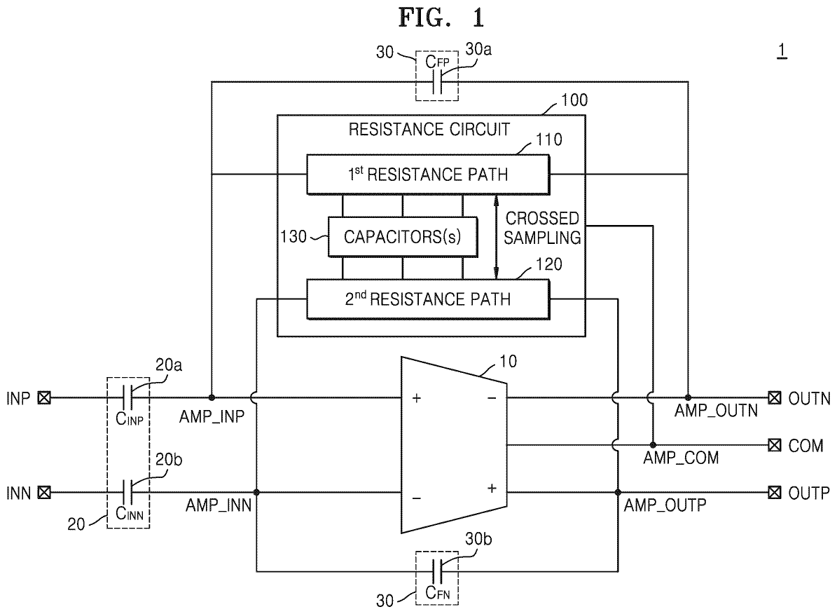

FIG. 1 is a diagram illustrating the high pass filter according to an embodiment.

Referring to FIG. 1, in an embodiment, the high pass filter 1 includes an amplifier 10, an input capacitor 20, a filter capacitor 30, and a resistance circuit 100.

The high pass filter 1 may be configured to pass frequency components higher than a cutoff frequency from among frequency components of an input signal and block frequency components lower than the cutoff frequency.

In an embodiment, the high pass filter 1 passes frequency components higher than the cutoff frequency from among the frequency components of the input signal with little attenuation and pass frequency components lower than the cutoff frequency with greater attenuation as the frequency decreases. Here, the cutoff frequency is a boundary frequency that separates a passband and a stopband and may mean a frequency at which the maximum gain of voltage or current drops by −3 dB (about 70.7%, 1/\sqrt{2}).

The input signal input to the high pass filter 1 may be a differential signal pair (e.g., INP and INN), and an output signal output from the high pass filter 1 may also be a differential signal pair (e.g., OUTN and OUTP). Here, a difference in current or voltage of the differential signal pair may correspond to one data signal.

Referring to FIG. 1, a first input signal INP may be received from a first input signal INP line, and a second input signal INN may be received from a second input signal INN line. A first output signal OUTN may be output from a first output signal OUTN line, and a second output signal OUTP may be output from a second output signal OUTP line. Here, the first input signal INP and the second input signal INN may be a differential signal pair, and the first output signal OUTN and the second output signal OUTP may be a differential signal pair.

The input capacitor 20 may be connected between an input signal line and an input terminal of the amplifier. The input capacitor 20 may block a direct current (DC) component of the input signal while allowing only an alternating current (AC) component to pass. The input capacitor 20 may connect a preceding circuit stage to a corresponding circuit stage by coupling the input signal to the high pass filter 1. The input capacitor 20 may block a low-frequency component of the input signal.

Referring to FIG. 1, the input capacitor 20 may include a first input capacitor 20a and a second input capacitor 20b. The first input capacitor 20a may be connected between the first input signal INP line and a node AMP_INP. The second input capacitor 20b may be connected between the second input signal INN line and a node AMP_INN.

The amplifier 10 may receive a differential input signal pair and output a differential output signal pair such that frequency components higher than a cutoff frequency from among frequency components of the differential input signal pair pass with little attenuation and frequency components lower than the cutoff frequency are attenuated more as the frequency decreases. For example, the amplifier 10 may receive a differential input signal pair and produce a differential output signal pair, allowing frequency components above the cutoff frequency to pass with minimal attenuation, while attenuating frequency components below the cutoff frequency progressively more as the frequency decreases. The amplifier 10 may be referred to as a fully differential operational amplifier.

When there is no feedback path connecting the input terminal and the output terminal to each other, the fully differential operational amplifier may receive a differential input signal pair and output a differential output signal pair by amplifying a voltage difference or a current difference of the differential input signal pair. For example, when there is no feedback path connecting the input terminal and the output terminal of an operational amplifier (fully differential operational amplifier) to each other, a relationship between the input signal and the output signal of the operational amplifier (fully differential operational amplifier) may be expressed by Equation 1 below.

$${V}_{OUT +} - {V}_{OUT -} = A * ( {V}_{IN +} - {V}_{IN -} ) \qquad [ Equation 1 ]$$

Here, V_{OUT+} and V_{OUT-} represent voltage levels of a differential output signal pair, A represents a gain of an operational amplifier (fully differential operational amplifier), and V_{IN+} and V_{IN-} represent voltage levels of a differential input signal pair.

Referring to FIG. 1, the amplifier 10 may include two input terminals and two output terminals. The two input terminals may include a non-inverting input terminal and an inverting input terminal, and the two output terminals may include a non-inverting output terminal and an inverting output terminal. Here, the amplifier 10 may determine a signal to be output from the non-inverting output terminal based on a signal applied to the inverting input terminal and determine a signal to be output from the inverting output terminal based on a signal applied to the non-inverting input terminal.

The non-inverting input terminal may be connected to the node AMP_INP and the inverting input terminal may be connected to the node AMP_INN. The inverting output terminal may be connected to a node AMP_OUTN, and the non-inverting output terminal may be connected to a node AMP_OUTP.

The amplifier 10 may further include an output common mode OCM terminal. The output common mode OCM terminal may be connected to an output common mode signal COM line. Referring to FIG. 1, a node AMP_COM may be connected between the output common mode OCM terminal and the output common mode OCM terminal.

The amplifier 10 may set an output common mode voltage level or monitor the output common mode voltage level based on the output common mode signal COM.

Here, the two differential output signals may swing around the output common mode voltage level. The output common mode voltage level may be represented using Equation 2 below.

$${V}_{OCM} = \frac{( {V}_{OUT +} - {V}_{OUT -} )}{2} \qquad [ Equation 2 ]$$

Here, V_{OCM} represents an output common mode voltage level, and V_{OUT+} and V_{OUT-} represent voltage levels of the differential output signal pair.

That is, the amplifier 10 may determine the output common mode voltage level based on the output common mode signal COM applied to the output common mode signal COM line and output two differential output signals such that the two differential output signals swing around the output common mode voltage level. That is, a DC level of the output signal may be set externally.

The amplifier 10 may monitor the output common mode voltage level for two differential output signals based on the output common mode signal COM output from the output common mode signal COM line. That is, the quality of the output signal may be monitored by detecting noise of the common mode voltage for output signals.

Hereinafter, it is assumed that the amplifier 10 determines the output common mode voltage level based on the output common mode signal COM applied to the output common mode signal COM line and outputs two differential output signals such that the two differential output signals swing around the output common mode voltage level.

The filter capacitor 30 may be connected between the input terminal of the amplifier 10 and the output terminal of the amplifier 10. The filter capacitor 30 may determine frequency characteristics of the high pass filter 1. For example, the cutoff frequency of the high pass filter 1 may be determined based on a capacitance of the filter capacitor 30. The filter capacitor 30 may change a phase of an output signal according to a frequency by causing a phase change in an input signal. For example, the cutoff frequency may be changed by using a filter capacitor 30 with a different capacitance or by using a variable capacitor with a controller that adjusts a capacitance of the variable capacitor using a control signal.

Referring to FIG. 1, the filter capacitor 30 may include a first filter capacitor 30a and a second filter capacitor 30b.

The first filter capacitor 30a may be connected between the node AMP_INP and the node AMP_OUTN. That is, the first filter capacitor 30a may be connected between the non-inverting input terminal and the inverting output terminal of the amplifier 10. For example, one end of the filter capacitor 30a may be connected to the node AMP_INP and the other end of the filter capacitor 30a may be connected to the node AMP_OUTN.

The second filter capacitor 30b may be connected between the inverting input terminal and the non-inverting output terminal of the amplifier 10. That is, the second filter capacitor 30b may be connected between the inverting input terminal and the non-inverting output terminal of the amplifier 10. For example, one end of the filter capacitor 30b may be connected to the node AMP_INN and the other end of the filter capacitor 30b may be connected to the node AMP_OUTP,

The resistance circuit 100 may be connected between the input terminal of the amplifier 10 and the output terminal of the amplifier 10. The resistance circuit 100 may determine the frequency characteristics of the high pass filter 1. For example, impedance of an output signal may be determined by the resistance circuit 100, and the cutoff frequency of the high pass filter 1 may be determined based on the impedance. The output signal may be a signal output from node AMP_OUTN or node AMP_OUTP.

Referring to FIG. 1, in an embodiment, the resistance circuit 100 includes a first resistance path 110, a second resistance path 120, and at least one capacitor 130.

The first resistance path 110 may be connected between the node AMP_INP and the node AMP_OUTN. That is, the first resistance path 110 may be connected between the non-inverting input terminal and the inverting output terminal of the amplifier 10.

The second resistance path 120 may be connected between the inverting input terminal and the non-inverting output terminal of the amplifier 10. That is, the second resistance path 120 may be connected between the inverting input terminal and the non-inverting output terminal of the amplifier 10.

A transfer function and cutoff frequency based on the first input capacitor 20a, the first filter capacitor 30a, and the first resistance path 110 may be represented using Equation 3 below, and a transfer function and cutoff frequency based on the second input capacitor 20b, the second filter capacitor 30b, and the second resistance path 120 may be represented using Equation 4 below.

$$\{ \begin{matrix}{H}_{1} ( s ) = \frac{{V}_{OUT -}}{{V}_{IN +}} = \frac{s {R}_{1} {C}_{FP}}{1 + {sR}_{1} {C}_{FP}} * \frac{{C}_{INP}}{{C}_{FP}} \\ {W}_{c 1} = \frac{1}{{R}_{1} {C}_{FP}} * \frac{1}{\sqrt{2 {C}_{INP}^{2} - {C}_{FP}^{2}}}\end{matrix} \qquad [ Equation 3 ]$$

$$\{ \begin{matrix}{H}_{2} ( s ) = \frac{{V}_{OUT +}}{{V}_{IN -}} = \frac{s {R}_{2} {C}_{FN}}{1 + {sR}_{2} {C}_{FN}} * \frac{{C}_{INN}}{{C}_{FN}} \\ {W}_{c2} = \frac{1}{{R}_{1} {C}_{FN}} * \frac{1}{\sqrt{2 {C}_{INP}^{2} - {C}_{FN}^{2}}}\end{matrix} \qquad [ Equation 4 ]$$

Here, H₁(s) and H₂(s) represent a first transfer function between a first output signal and a first input signal, and a second transfer function between a second output signal and a second input signal, respectively. R₁ and R₂ represent resistance of the first resistance path and resistance of the second resistance path, respectively. CFP and CFN represent capacitance of the first filter capacitor and capacitance of the second filter capacitor, respectively. C_{INP} and C_{INN} represent capacitance of the first input capacitor and capacitance of the second input capacitor, respectively. W_{c1} and W_{c2} represent a cutoff frequency of the first transfer function and a cutoff frequency of the second frequency, respectively.

An audible frequency range of humans is be between about 20 Hz to about 20,000 Hz. When the high pass filter 1 according to an embodiment of the inventive concept is provided in an acoustic device, a cutoff frequency may be 20 Hz or lower. This cutoff frequency may be achieved by increasing capacitance or resistance. However, an increase in the capacitance in an integrated circuit causes very low area cost efficiency since high capacitance capacitors typically require a large physical area. Thus, increasing the resistance is more efficient in terms of area utilization.

Therefore, the resistance circuit 100 according to the inventive concept may provide high resistance to the high pass filter 1 in a smaller area in an integrated circuit. The resistance circuit 100 may be implemented by a pseudo resistor. Alternately, the resistance circuit 100 may be implemented by a sample and averaging feedback resistor (SAFR).

The resistance circuit 100 according to the inventive concept provides adjustable resistance rather than fixed resistance to the high pass filter 1. In an embodiment, the high pass filter 1 is configured as a capacitive programable gain amplifier (PGA).

The resistance circuit 100 according to the inventive concept may include the first resistance path 110 and the second resistance path 120 and may further include at least one capacitor 130 connected between the first resistance path 110 and the second resistance path 120, thereby increasing the efficiency of effective capacitance that determines resistance.

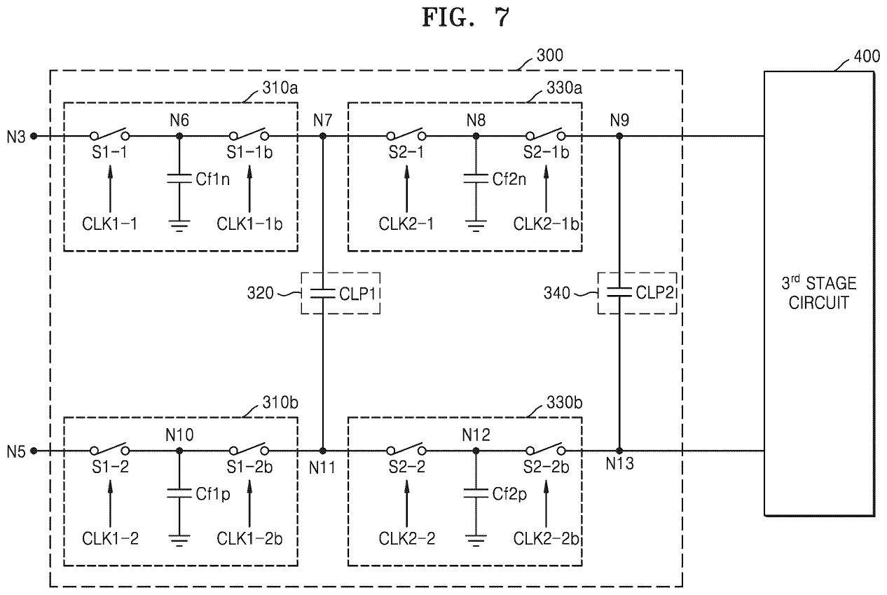

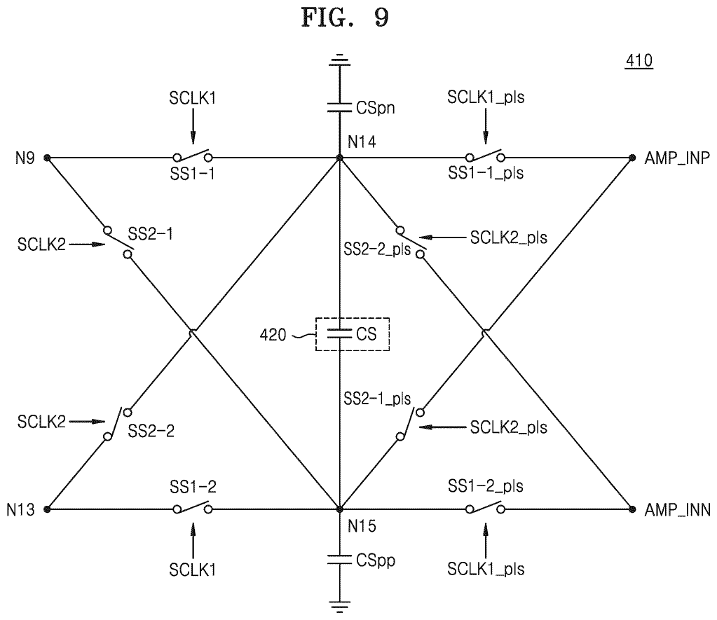

Here, the first resistance path 110 may mean a resistance path connecting the node AMP_INP, which connects the filter capacitor 30 to the non-inverting input terminal, to the node AMP_OUTN, which connects the filter capacitor 30 to the inverting output terminal, within the resistance circuit 100. The second resistance path 120 may mean a resistance path connecting the node AMP_INN, which connects the filter capacitor 30 to the inverting input terminal, to the node AMP_OUTP, which connects the filter capacitor 30 to the non-inverting output terminal, within the resistance circuit 100. The at least one capacitor 130 may include a capacitor CLP1 (FIG. 7), a capacitor CLP2 (FIG. 7), or a capacitor CS (FIG. 9).

The resistance circuit 100 according to the inventive concept includes a resistance ladder, and thus resistance of the resistance circuit 100 may be increased based on an attenuation ratio of the resistance ladder. Accordingly, the resistance circuit 100 may provide primarily increased effective resistance to the high pass filter 1.

The resistance circuit 100 may include a resistance ladder, and thus resistance of the resistance circuit 100 may be increased based on the number of resistors provided in the resistance ladder. That is, the resistance of the resistance circuit 100 may be increased by linearly controlling the resistance of the resistance circuit 100. For example, the resistance ladder may be a network of resistors connected in specific arrangement, and by selectively engaging or bypassing certain resistors in the ladder (e.g., through switches or digital control), the total resistance of the circuit can be dynamically adjusted.

When the resistance circuit 100 includes the resistance ladder, an unintended DC offset may increase in the output signal. In an embodiment, the unintended DC offset in the output signal is removed in a second stage circuit 300 and/or a third stage circuit 400 described below.

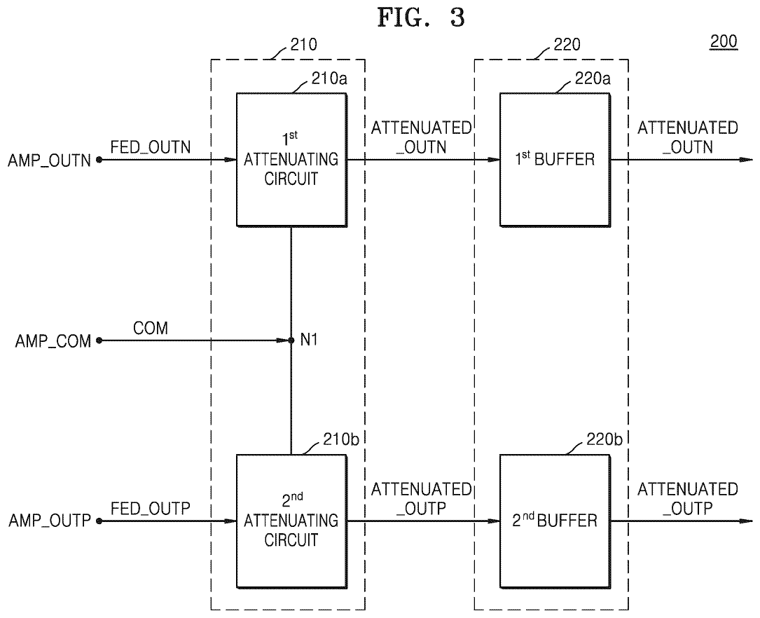

The resistance circuit 100 according to an embodiment of the inventive concept includes a buffer 220 (FIG. 3) that buffers an attenuated signal, thereby preventing intermodulation between a frequency of the input signal and a clock signal applied to the second stage circuit 300 and/or the third stage circuit 400 to be described below.

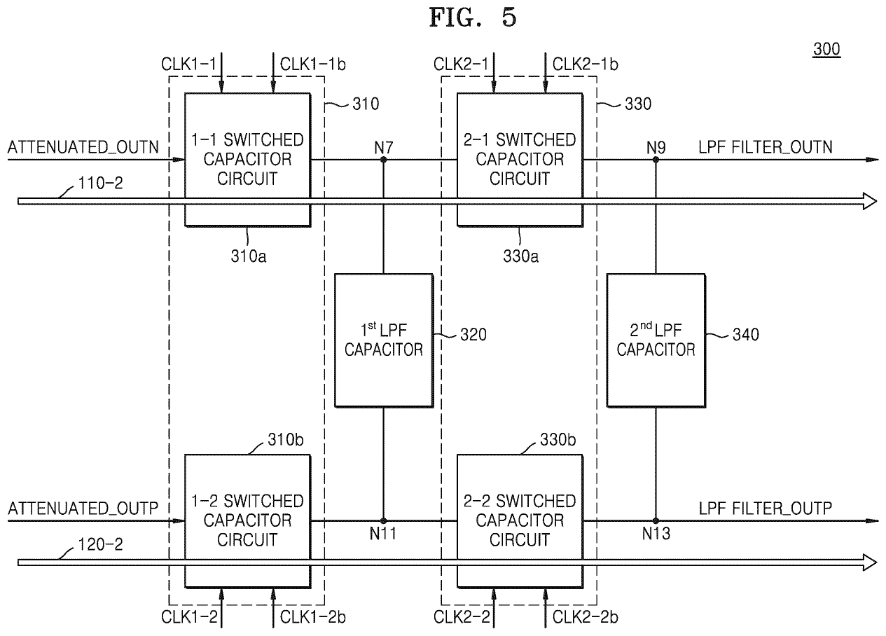

The resistance circuit 100 according to an embodiment of the inventive concept includes a second-order low-pass filter, and a first low pass filter (LPF) capacitor 320 (FIG. 5) and/or a second LPF capacitor 340 (FIG. 5) may be connected between the first resistance path 110 and the second resistance path 120, thereby maximizing an effect of a low-pass filtering operation. That is, the overall capacitance may be increased more than when a capacitor is independently added to each resistance path by connecting at least one shared capacitor between the first resistance path 110 and the second resistance path 120. For example, the effective capacitance of the entire circuit may be 2C and the overall capacitance may be increased by connecting the capacitance C to be added to the first resistance path 110 to the capacitance C to be added to the second resistance path 120 in parallel rather than adding an independent capacitance C to the first resistance path 110 and adding an independent capacitance C to the second resistance path 120. For instance, the effective capacitance of the entire circuit could be 2C, and this overall capacitance can be increased by connecting the capacitance C for the first resistance path 110 in parallel with the capacitance C for the second resistance path 120, rather than adding separate capacitances of C to each path individually. That is, in terms of area efficiency of the integrated circuit, the overall capacitance may be increased by connecting a shared capacitor between the resistance paths. This may lower the cutoff frequency of the low pass filter (e.g., the second stage circuit 300), allowing lower frequency signals to pass and higher frequency signals to be blocked more effectively.

In addition, according to an embodiment, the resistance circuit 100 may reduce mismatch between the resistance of the first resistance path 110 and the resistance of the second resistance path 120 by connecting the first resistance path 110 and the second resistance path 120 in the third stage circuit 400 of the resistance circuit 100 to be described below with the capacitor CS. Accordingly, an unintended DC offset may be removed from the output signal.

The third stage circuit 400 of the resistance circuit 100 to be described below may sample (i.e., cross sample) the corresponding low filter output signal by alternately using two parasitic capacitors for respective phases (e.g., a first phase or a second phase), thereby averaging mismatch between the resistance of the first resistance path 110 and the resistance of the second resistance path 120 caused by the parasitic capacitors. Here, averaging may mean reducing an influence of parasitic capacitors by spreading the influence of the parasitic capacitors over several cycles.

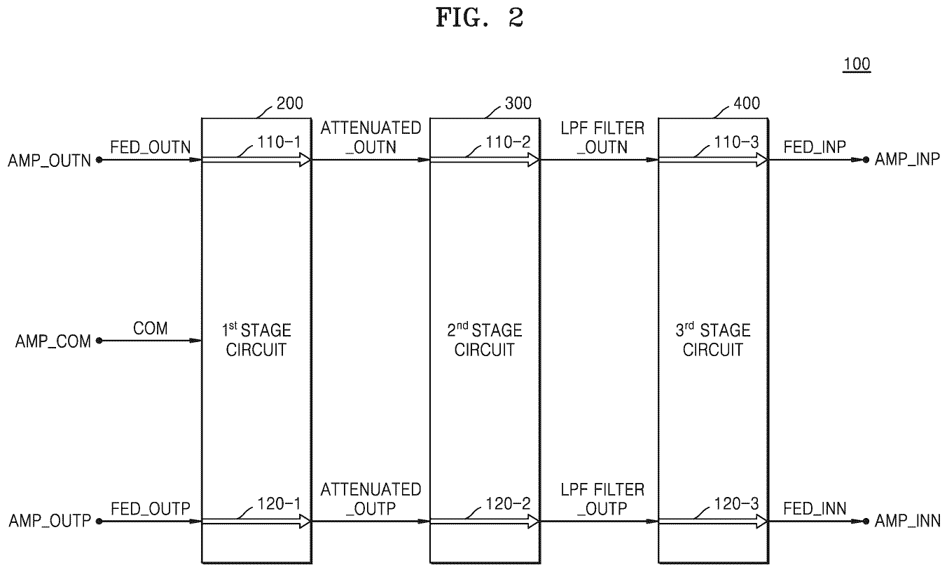

Operations of the resistance circuit 100 described above will be described in detail with reference to FIGS. 2 to 15.

FIG. 2 is a diagram illustrating a resistance circuit according to an embodiment.

The resistance circuit 100 is illustrated as including three stages, but is not limited thereto. Referring to FIG. 2, the resistance circuit 100 may include a first stage circuit 200, the second stage circuit 300, and the third stage circuit 400.

Referring to FIGS. 1 and 2, the first stage circuit 200 may be connected between the output terminal of the amplifier 10 and the second stage circuit 300. In detail, the first stage circuit 200 may be connected between the node AMP_OUTN and the second stage circuit 300, and the first stage circuit 200 may be connected between the node AMP_OUTP and the second stage circuit 300.

Referring to FIG. 2, the second stage circuit 300 may be connected between the first stage circuit 200 and the third stage circuit 400.

Referring to FIGS. 1 and 2, the third stage circuit 400 may be connected between the input terminal of the amplifier 10 and the second stage circuit 300. In detail, the third stage circuit 400 may be connected between the node AMP_INP and the second stage circuit 300, and third stage circuit 400 may be connected between the node AMP_INN and the second stage circuit 300.

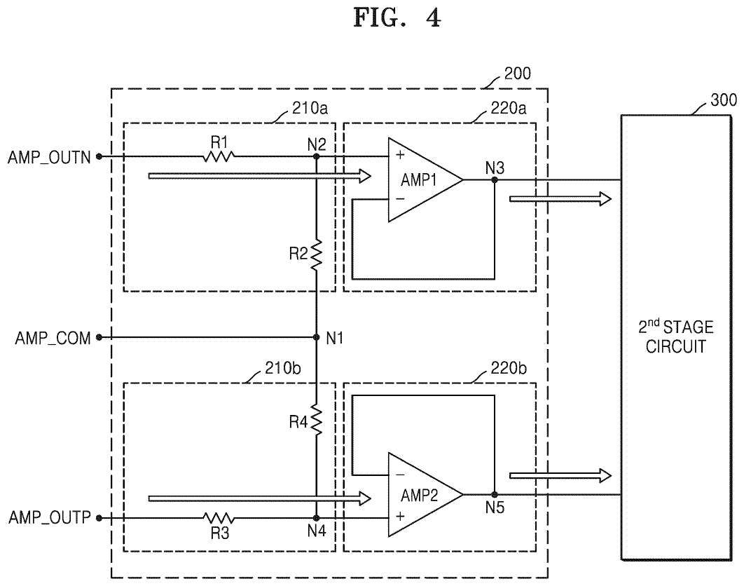

Referring to FIGS. 1 and 2, the first stage circuit 200 receives an amplifier feedback output signal FED_OUTN or FED_OUTP applied from the node AMP_OUTN or AMP_OUTP connecting the output terminal of the amplifier 10 to the filter capacitor 30 and output an attenuated signal ATTENUATED_OUTN or ATTENUATED_OUTP by attenuating a voltage level of the amplifier feedback output signal FED_OUTN or FED_OUTP. For example, the first stage circuit 200 may receive an amplifier feedback output signal (FED_OUTN or FED_OUTP) from the node AMP_OUTN or AMP_OUTP, which connects the amplifier's output terminal to the filter capacitor 30. It then outputs an attenuated signal (ATTENUATED_OUTN or ATTENUATED_OUTP) by reducing the voltage level of the received feedback output signal (FED_OUTN or FED_OUTP). The first stage circuit 200 may further include the buffer 220 (FIG. 3) that buffers the attenuated signal ATTENUATED_OUTN or ATTENUATED_OUTP and outputs the attenuated signal ATTENUATED_OUTN or ATTENUATED_OUTP to the second stage circuit 300. This will be described in detail with reference to FIGS. 4 and 5.

Referring to FIG. 2, the second stage circuit 300 receives the attenuated signal ATTENUATED_OUTN or ATTENUATED_OUTP and performs a low pass filtering operation on the attenuated signal ATTENUATED_OUTN or ATTENUATED_OUTP to output a low pass filter output signal LPF FILTER_OUTN or LPF FILTER_OUTP. That is, the second stage circuit 300 may provide the low pass filter output signal LPF FILTER_OUTN or LPF FILTER_OUTP to the third stage circuit 400. A low pass filtering operation of the second stage circuit 300 will be described in detail with reference to FIGS. 5 to 7.

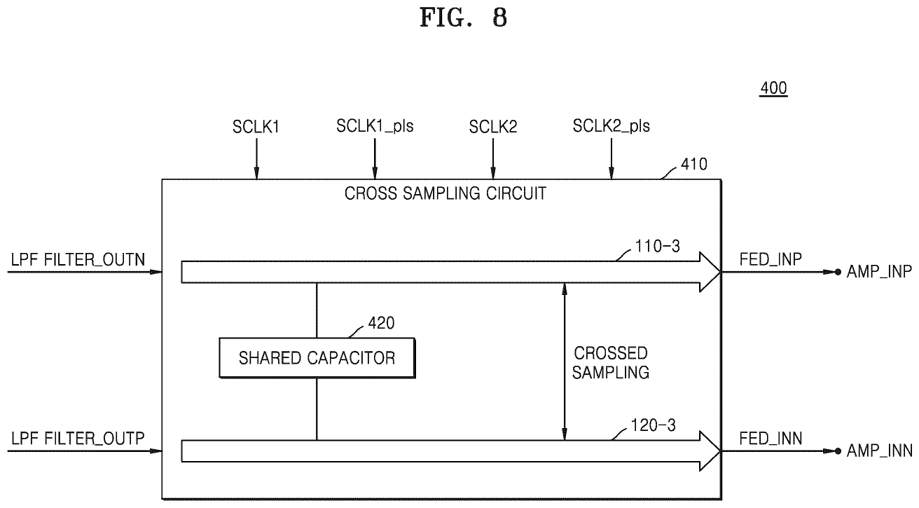

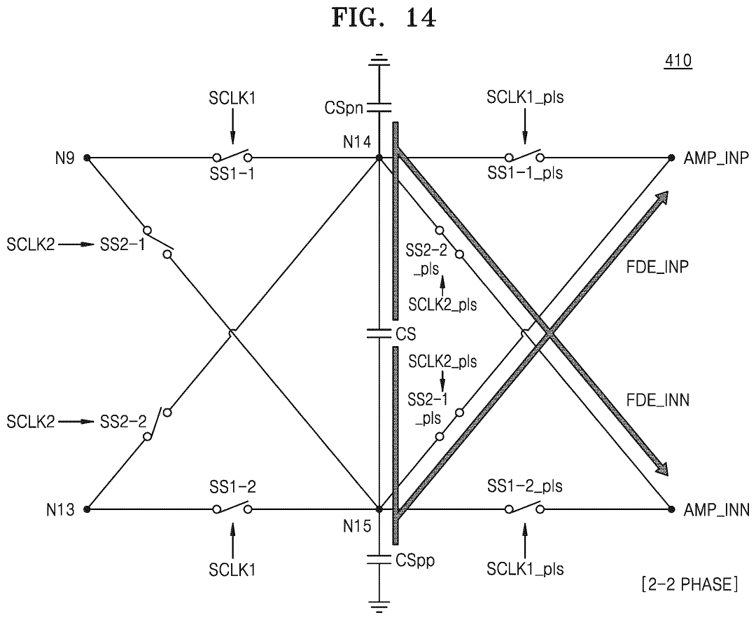

Referring to FIGS. 1 and 2, the third stage circuit 400 may receive the low filter output signal LPF FILTER_OUTN or LPF FILTER_OUTP and perform a cross sampling operation on the low pass filter output signal LPF FILTER_OUTN or LPF FILTER_OUTP to output a feedback input signal FED_INP or FED_INN to a node AMP_INP or AMP_INN connecting the input terminal of the amplifier 10 to the filter capacitor 30. This will be described in detail with reference to FIGS. 8 and 14.

The second stage circuit 300 may be referred to as a fast stage. The third stage circuit 400 to be described below may use a sample clock signal. In an embodiment, a frequency of the sample clock signal used in the third stage circuit 400 is lower than a frequency of the clock signal used in the second stage circuit 300. Thus the third stage circuit 400 may be referred to as a slow stage.

The first resistance path 110 described with reference to FIG. 1 may include a 1^{st}-1 resistance path 110-1, a 1^{st}-2 resistance path 110-2, and a 1^{st}-3 resistance path 110-3. The second resistance path 120 described with reference to FIG. 1 may include a 2^{nd}-1 resistance path 120-1, a 2^{nd}-2 resistance path 120-2, and a 2^{nd}-3 resistance path 120-3. Here, the first stage circuit 200 may include the 1^{st}-1 resistance path 110-1 and the 2^{nd}-1 resistance path 120-1, the second stage circuit 300 may include the 1^{st}-2 resistance path 110-2 and the 2^{nd}-2 resistance path 120-2, and the third stage circuit 400 may include the 1^{st}-3 resistance path 110-3 and the 2^{nd}-3 resistance path 120-3.

FIG. 3 is a diagram illustrating a first stage circuit according to an embodiment. FIG. 4 is a diagram showing an equivalent circuit of a first stage circuit according to an embodiment.

Referring to FIG. 3, in an embodiment, the first stage circuit 200 includes an attenuating circuit 210 and the buffer 220.

The attenuating circuit 210 may receive an amplifier feedback output signal applied from the node AMP_OUTN or AMP_OUTP connecting the output terminal of the amplifier 10 to the filter capacitor 30 and output an attenuated signal by attenuating a voltage level of the amplifier feedback output signal.

In an embodiment, the attenuating circuit 210 is implemented by a resistance ladder. When the attenuating circuit 210 is implemented as a resistance ladder, the resistance of the resistance circuit 100 may increase based on the attenuation ratio of the resistance ladder. Accordingly, the resistance circuit 100 may provide primarily increased effective resistance to the high pass filter 1.

When the attenuating circuit 210 is implemented by a resistance ladder, a resistance of the resistance circuit 100 may be increased based on the number of resistors provided in the resistance ladder. That is, the resistance of the resistance circuit 100 may be increased by linearly adjusting the resistance of the resistance circuit 100.

When the attenuating circuit 210 is implemented by a resistance ladder, an unintended DC offset may increase in the output signal. However, the unintended DC offset in the output signal may be removed in the second stage circuit 300 and/or the third stage circuit 400 described below.

Here, each of the output signals may swing around a specific voltage other than the voltage level of the output common mode signal COM, and the unintended DC offset may refer to this specific voltage. For example, when the unintended DC offset is present, the output signals may swing around a voltage level different from the voltage level of the output common mode signal COM.

The attenuating circuit 210 may receive the output common mode signal COM applied from a node AMP_COM connecting the output common mode signal COM line to the output common mode OCM terminal of the amplifier 10.

Referring to FIG. 3, in an embodiment, the attenuating circuit 210 includes a first attenuating circuit 210a and a second attenuating circuit 210b. The first attenuating circuit 210a may receive a first amplifier feedback output signal FED_OUTN applied from the node AMP_OUTN and output a first attenuated signal ATTENUATED_OUTN by attenuating a voltage level of the first amplifier feedback output signal FED_OUTN. The second attenuating circuit 210b may receive a second amplifier feedback output signal FED_OUTP applied from the node AMP_OUTP and output a second attenuated signal ATTENUATED_OUTP by attenuating a voltage level of the second attenuated signal ATTENUATED_OUTP.

Referring to FIG. 3, a node N1 connects the first attenuating circuit 210a to the second attenuating circuit 210b, and the node N1 may receive the output common mode signal COM applied from the node AMP_COM. That is, the first attenuating circuit 210a and the second attenuating circuit 210b may receive the output common mode signal COM through the node N1.

The buffer 220 may receive an attenuated signal, buffer the attenuated signal, and provide the buffered attenuated signal to a next circuit (e.g., the second stage circuit 300). Intermodulation between the frequency of the input signal and the clock signal applied to the second stage circuit 200 and/or the third stage circuit 300 described below may be prevented by buffering the attenuated signal with the buffer 220. For example, when the input signal interacts with the clock signal to produce unwanted signals, this may be referred to an intermodulation.

Here, the intermodulation may mean that a frequency component corresponding to the sum or difference of an integer multiple of a frequency of the input signal and an integer multiple of a frequency of the clock signal is generated as noise in the output signal.

Referring to FIG. 3, in an embodiment, the buffer 220 includes a first buffer 220a (e.g., a first buffer circuit) and a second buffer 220b (e.g., a second buffer circuit). The first buffer 220a may receive the first attenuated signal ATTENUATED_OUTN, buffer the first attenuated signal ATTENUATED_OUTN, and provide the buffered first attenuated signal ATTENUATED_OUTN to the second stage circuit 300. The second buffer 220b may receive the second attenuated signal ATTENUATED_OUTP, buffer the second attenuated signal ATTENUATED_OUTP, and provide the buffered second attenuated signal ATTENUATED_OUTP to the second stage circuit 300.

FIG. 4 is a diagram showing an equivalent circuit of the first stage circuit 200 according to an embodiment.

Referring to FIG. 4, the node N1 may be connected to the node AMP_COM (or the output common mode signal COM line), and the output common mode signal COM may be applied to node N1.

In an embodiment, the first attenuating circuit 210a is implemented by a resistance ladder. Referring to FIG. 4, the first attenuating circuit 210a may include a resistor R1 and a resistor R2. The resistor R1 may be connected between the node AMP_OUTN and a node N2. The resistor R2 may be connected between the node N2 and the node N1.

Here, referring to FIGS. 3 and 4, the first attenuating circuit 210a may output the first attenuated signal ATTENUATED_OUTN to the node N2 by attenuating a voltage level of the first amplifier feedback output signal FED_OUTN based on the resistance of each of the resistor R1 and the resistor R2.

In an embodiment, the second attenuating circuit 210b is implemented by a resistance ladder. Referring to FIG. 4, the second attenuating circuit 210b may include a resistor R3 and a resistor R4. The resistor R3 may be connected between the node AMP_OUTP and a node N4. The resistor R4 may be connected between the node N1 and the node N4.

Here, referring to FIGS. 3 and 4, the second attenuating circuit 210b may output the second attenuated signal ATTENUATED_OUTP to the node N4 by attenuating a voltage level of the second attenuated signal ATTENUATED_OUTP based on the resistance of each of the resistor R3 and the resistor R4.

In an embodiment, the first buffer 220a is implemented by an operational amplifier AMP1 as shown in FIG. 4. The non-inverting input terminal of the operational amplifier AMP1 may be connected to the node N2, and the inverting input terminal of the operational amplifier AMP1 may be connected to the output terminal at a node N3. The node N3 may connect the first stage circuit 200 to the second stage circuit 300.

Here, referring to FIGS. 3 and 4, the first attenuated signal ATTENUATED_OUTN applied from the node N2 may be applied to a non-inverting terminal of the operational amplifier AMP1. In an embodiment, voltage levels of the non-inverting terminal and the inverting terminal of the operational amplifier AMP1 are the same. Thus the operational amplifier AMP1 may output the first attenuated signal ATTENUATED_OUTN to the node N3 that connects the inverting terminal of the operational amplifier AMP1 to the output terminal of the operational amplifier AMP1. According to a buffering operation of the operational amplifier AMP1 described above, intermodulation between a frequency of the first input signal (or the first attenuated signal ATTENUATED_OUTN) and a clock signal applied to the second stage circuit 200 and/or the third stage circuit 300 to be described below may be prevented.

In an embodiment, the second buffer 220b is implemented by an operational amplifier AMP2 as shown in FIG. 4. The non-inverting input terminal of the operational amplifier AMP2 may be connected to the node N4, and the inverting input terminal of the operational amplifier may be connected to the output terminal at a node N5. The node N5 may connect the first stage circuit 200 to the second stage circuit 300.

Here, referring to FIGS. 3 and 4, the second attenuated signal ATTENUATED_OUTP applied from the node N4 may be applied to a non-inverting terminal of the operational amplifier AMP2. In an embodiment, voltage levels of the non-inverting terminal and the inverting terminal of the operational amplifier AMP2 are the same. Thus the operational amplifier AMP2 may output the second attenuated signal ATTENUATED_OUTP to the node N5 that connects the inverting terminal of the operational amplifier AMP2 to the output terminal of the operational amplifier AMP2. According to a buffering operation of the operational amplifier AMP2 described above, intermodulation between a frequency of the second input signal (or the second attenuated signal ATTENUATED_OUTP) and a clock signal applied to a second stage circuit 200 and/or a third stage circuit 300 to be described below may be prevented.

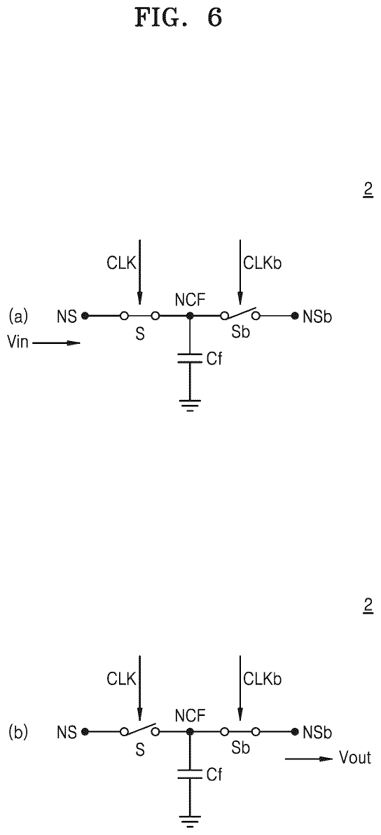

FIG. 5 is a diagram illustrating a second stage circuit according to an embodiment. FIG. 6 is a diagram to explain a switched capacitor circuit. FIG. 7 is a diagram showing an equivalent circuit of a second stage circuit according to an embodiment.

Referring to FIG. 5, in an embodiment, the second stage circuit 300 includes a first switched capacitor circuit 310, a first LPF capacitor 320, a second switched capacitor circuit 330, and the second LPF capacitor 340.

The first switched capacitor circuit 310 and the second switched capacitor circuit 330 may provide resistance to the resistance circuit 100 based on a frequency of a clock signal applied to switches. First, with reference to FIG. 6, the switched capacitor circuit will be described in detail. The switched capacitor circuit in FIG. 6 may be used to implement a switched capacitor circuit of the first switched capacitor circuit 310 or the second switched capacitor circuit 330.

Referring to (a) and (b) of FIG. 6, one switched capacitor circuit 2 may include a switch S, a switch Sb, and a capacitor Cf. In an embodiment, the switch S and the switch Sb are not turned on or off simultaneously, but are turned on or off alternately.

Referring to (a) of FIG. 6, when the switch S is turned on in response to a clock signal CLK and the switch Sb is turned off in response to a clock signal CLKb, a voltage Vin applied to a node NS may be transmitted to the capacitor Cf.

Referring to (b) of FIG. 6, when the switch S is turned off in response to the clock signal CLK and the switch Sb is turned on in response to the clock signal CLKb, a voltage Vout may be applied to a node NSb based on charge stored in the capacitor Cf.

Effective resistance between the node NS and the node NSb may be represented using Equation 5 below.

$${R}_{equivalent} = \frac{( {V}_{in} - {V}_{out} )}{{I}_{in - out}} = \frac{( {V}_{in} - {V}_{out} )}{{C}_{f} ( {V}_{in} - {V}_{out} ) f} = \frac{1}{{C}_{f} f} \qquad [ Equation 5 ]$$

Here, R_{equivalent} represents effective resistance, C_{f} represents capacitance of the capacitor Cf, and f represents a switching frequency of the switch S and the switch Sb. Here, the switching frequency may correspond to a frequency of a clock signal.

That is, the resistance of the switched capacitor circuit 2 may be determined based on a frequency of a clock signal and capacitance of a capacitor. For example, resistance of the switched capacitor circuit 2 may be controlled by changing the frequency of the clock signal.

Returning back to FIG. 5, the first switched capacitor circuit 310 may include a 1^{st}-1 switched capacitor circuit 310a and a 1^{st}-2 switched capacitor circuit 310b. Referring to FIG. 5, the second switched capacitor circuit 330 may include a 2^{nd}-1 switched capacitor circuit 330a and a 2^{nd}-2 switched capacitor circuit 330b.

Here, the switched capacitor circuits 310a, 310b, 330a, and 330b may be implemented as the switched capacitor circuit 2 described with reference to FIG. 6. Referring to FIG. 5, the switched capacitor circuits 310a, 310b, 330a, and 330b may provide resistance to the second stage circuit 300 (or the resistance circuit 100) based on frequencies of the clock signals CLK1-1, CLK1-1b, CLK1-2, CLK1-2b, CLK2-1, CLK2-1b, CLK2-2, and CLK2-2b.

Referring to FIG. 5, the 1^{st}-1 switched capacitor circuit 310a may be connected between the first stage circuit 200 and a node N7. The 1^{st}-2 switched capacitor circuit 310b may be connected between the first stage circuit 200 and a node N11. The first LPF capacitor 320 may be connected between the node N7 and the node N11.

Here, the 1^{st}-1 switched capacitor circuit 310a may receive the first attenuated signal ATTENUATED_OUTN, and the 1^{st}-1 switched capacitor circuit 310a and the first LPF capacitor 320 may perform a low filtering operation on the first attenuated signal ATTENUATED_OUTN to output a first attenuated signal that is primarily low-pass filtered at the node N7.

Here, the 1^{st}-2 switched capacitor circuit 310b may receive the second attenuated signal ATTENUATED_OUTP, and the 1^{st}-2 switched capacitor circuit 310b and the first LPF capacitor 320 may perform a low filtering operation on the second attenuated signal ATTENUATED_OUTP to output a first attenuated signal that is primarily low-pass filtered at the node N11.

Referring to FIG. 5, the 2^{nd}-1 switched capacitor circuit 330a may be connected between the node N7 and a node N9. The 2^{nd}-2 switched capacitor circuit 330b may be connected between the node N11 and a node N13. The second LPF capacitor 340 may be connected between the node N9 and the node N13.

Here, the 2^{nd}-1 switched capacitor circuit 330a may receive a first attenuated signal that is primarily low-filtered at the node N7, and the 2^{nd}-1 switched capacitor circuit 330a and the second LPF capacitor 340 may perform a low filtering operation on the first attenuated signal that is primarily low-filtered to output a first low-pass filter output signal LPF FILTER_OUTN that is finally low-pass filtered at the node N9.

Here, the 2^{nd}-2 switched capacitor circuit 330b may receive a second attenuated signal that is primarily low-filtered at the node N11, and the 2^{nd}-2 switched capacitor circuit 330b and the second LPF capacitor 340 may perform a low filtering operation on the second attenuated signal that is primarily low-filtered to output a second low-pass filter output signal LPF FILTER_OUTP that is finally low-pass filtered at the node N13.

That is, the second stage circuit 300 may operate as a second-order low-pass filter. An effect of the low-pass filtering operation may be maximized by connecting the first LPF capacitor 320) and/or the second LPF capacitor 340 between the 1^{st}-2 resistance path 110-2 and the 2^{nd}-2 resistance path 120-2. Here, each of the first LPF capacitor 320 and the second LPF capacitor 340 may be referred to as a shared capacitor.

The overall capacitance may be increased more than when a capacitor is independently added to each resistance path by connecting at least one shared capacitor between the 1^{st}-2 resistance path 110-2 and the 2^{nd}-2 resistance path 120-2. For example, the effective capacitance of the entire circuit may be 2C and the overall capacitance may be increased by connecting the capacitance C to be added to the 1^{st}-2 resistance path 110-2 to the capacitance C to be added to the 2^{nd}-2 resistance path 120-2 in parallel rather than adding an independent capacitance C to the 1^{st}-2 resistance path 110-2 and adding an independent capacitance C to the 2^{nd}-2 resistance path 120-2. For instance, the effective capacitance of the entire circuit could be 2C, and the total capacitance can be increased by connecting the capacitance C intended for the 1^{st}-2 resistance path 110-2 in parallel with the capacitance C intended for the 2^{nd}-2 resistance path 120-2, instead of adding separate capacitances of C to each path individually. That is, in terms of area efficiency of the integrated circuit, the overall capacitance may be increased by connecting a shared capacitor between the resistance paths. This may lower the cutoff frequency of the low pass filter (e.g., the second stage circuit 300), allowing lower frequency signals to pass and higher frequency signals to be blocked more effectively.

FIG. 7 is a diagram showing an equivalent circuit of the second stage circuit 300 according to an embodiment.

Referring to FIG. 4 and FIG. 7, the 1^{st}-1 switched capacitor circuit 310a may be connected between the node N3 and the node N7. In an embodiment, the 1^{st}-1 switched capacitor circuit 310a includes a switch S1-1, a switch S1-1b, and a capacitor Cf1n. The switch S1-1 may be connected between the node N3 and a node N6. The capacitor Cf1n may be connected between the node N6 and a ground voltage line. The switch S1-1b may be connected between the node N6 and the node N7.

Here, the switch S1-1 may be turned off or turned on based on a clock signal CLK1-1, and the switch S1-1b may be turned off or turned on based on a clock signal CLK1-1b. In an embodiment, the clock signal CLK1-1 and the clock signal CLK1-1b have opposite phases. Here, the switch S1-1 and the switch S1-1b are not turned on or off simultaneously. For example, when the switch S1-1 is turned on, the switch S1-1b is turned off, and when the switch S1-1 is turned off, the switch S1-1b is turned on. That is, the switch S1-1 and the switch S1-1b may be alternately turned on or off based on the clock signal CLK1-1 and the clock signal CLK1-1b.

Referring to FIG. 4 and FIG. 7, the 1^{st}-2 switched capacitor circuit 310b may be connected between the node N5 and a node N10. In an embodiment, the 1^{st}-2 switched capacitor circuit 310b includes a switch S1-2, a switch S1-2b, and a capacitor Cf1p. The switch S1-2 may be connected between the node N5 and the node N10. The capacitor Cf1p may be connected between the node N10 and a ground voltage line. The switch S1-2b may be connected between the node N10 and the node N11.

Here, the switch S1-2 may be turned off or turned on based on a clock signal CLK1-2, and the switch S1-2b may be turned off or turned on based on a clock signal CLK1-2b. In an embodiment, the clock signal CLK1-2 and the clock signal CLK1-2b have opposite phases. Here, the switch S1-2 and the switch S1-2b are not turned on or off simultaneously. For example, when the switch S1-2 is turned on, the switch S1-2b is turned off, and when the switch S1-2 is turned off, the switch S1-2b is turned on. That is, the switch S1-2 and the switch S1-2b may be alternately turned on or off based on the clock signal CLK1-2 and the clock signal CLK1-2b.

Referring to FIG. 7, the first LPF capacitor 320 may be a single capacitor CLP1. The capacitor CLP1 may be connected between the node N7 and the node N11.

Referring to FIG. 7, the 2^{nd}-1 switched capacitor circuit 330a may be connected between the node N7 and the node N9. In an embodiment, the 2^{nd}-1 switched capacitor circuit 330a includes a switch S2-1, a switch S2-1b, and a capacitor Cf2n. The switch S2-1 may be connected between the node N7 and a node N8. The capacitor Cf2n may be connected between the node N8 and a ground voltage line. The switch S2-1b may be connected between the node N8 and the node N9.

Here, the switch S2-1 may be turned off or turned on based on a clock signal CLK2-1, and the switch S2-1b may be turned off or turned on based on a clock signal CLK2-1b. In an embodiment, the clock signal CLK2-1 and the clock signal CLK2-1b have opposite phases. Here, the switch S2-1 and the switch S2-1b are not turned on or off simultaneously. For example, when the switch S2-1 is turned on, the switch S2-1b is turned off, and when the switch S2-1 is turned off, the switch S1-1b is turned on. That is, the switch S2-1 and the switch S2-1b may be alternately turned on or off based on the clock signal CLK2-1 and the clock signal CLK2-1b.

Referring to FIG. 7, the 2^{nd}-2 switched capacitor circuit 330b may be connected between the node N11 and the node N13. In an embodiment, the 2^{nd}-2 switched capacitor circuit 330b includes a switch S2-2, a switch S2-2b, and a capacitor Cf2p. The switch S2-2 may be connected between the node N11 and a node N12. The capacitor Cf2p may be connected between the node N12 and a ground voltage line. The switch S2-2b may be connected between the node N12 and a node N13.

Here, the switch S2-2 may be turned off or turned on based on a clock signal CLK2-2, and the switch S2-2b may be turned off or turned on based on a clock signal CLK2-2b. In an embodiment, the clock signal CLK2-2 and the clock signal CLK2-2b have opposite phases. Here, the switch S2-2 and the switch S2-2b are not turned on or off simultaneously. For example, when the switch S2-2 is turned on, the switch S2-2b is turned off, and when the switch S2-2 is turned off, the switch S2-2b is turned on. That is, the switch S2-2 and the switch S2-2b may be alternately turned on or off based on the clock signal CLK2-2 and the clock signal CLK2-2b.

Referring to FIG. 7, the second LPF capacitor 340 may include one capacitor CLP2. The capacitor CLP2 may be connected between the node N9 and the node N13.

In some embodiments, the clock signal CLK1-1, the clock signal CLK1-2, the clock signal CLK2-1, and the clock signal CLK2-2 have the same phase, and the clock signal CLK1-1b, the clock signal CLK1-2b, the clock signal CLK2-1b, and the clock signal CLK2-2b have the same phase. That is, the switch S1-1, the switch S1-2, the switch S2-1, and the switch S2-2 may be turned on or off simultaneously based on the clock signal CLK1-1, the clock signal CLK1-2, the clock signal CLK2-1, and the clock signal CLK2-2, respectively. The switch S1-1b, the switch S1-2b, the switch S2-1b, and the switch S2-2b may be turned on or off simultaneously based on the clock signal CLK1-1b, the clock signal CLK1-2b, the clock signal CLK2-1b, and the clock signal CLK2-2b, respectively. In some embodiments, to prevent in-band interference, the lowest frequency of the clock signals CLK1-1, CLK1-1b, CLK1-2, CLK1-2b, CLK2-1, CLK2-1b, CLK2-2, and CLK2-2b may be 48 KHz.

Referring to FIGS. 5 and 7, the second stage circuit 300 may provide the first low-pass filter output signal LPF FILTER_OUTN to the third stage circuit 400 at the node N9. The second stage circuit 300 may provide the second low-pass filter output signal LPF FILTER_OUTP to the third stage circuit 400 at the node N13.

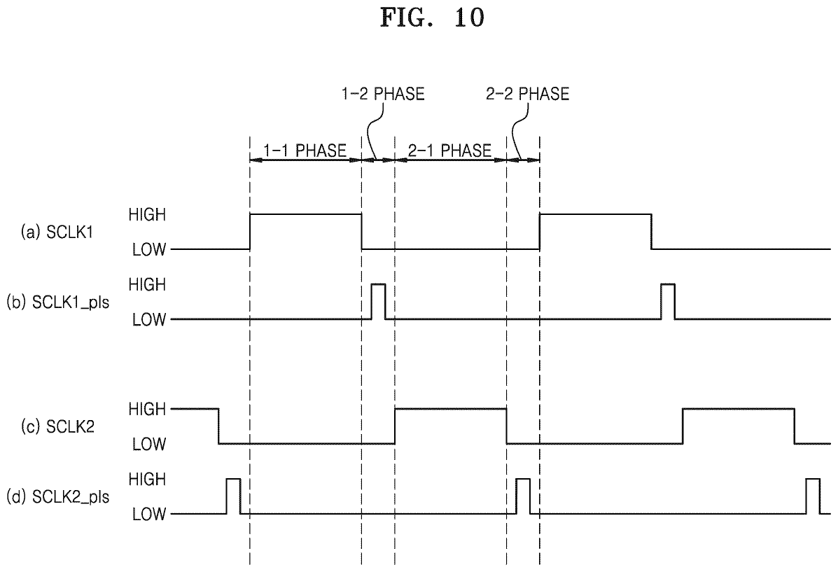

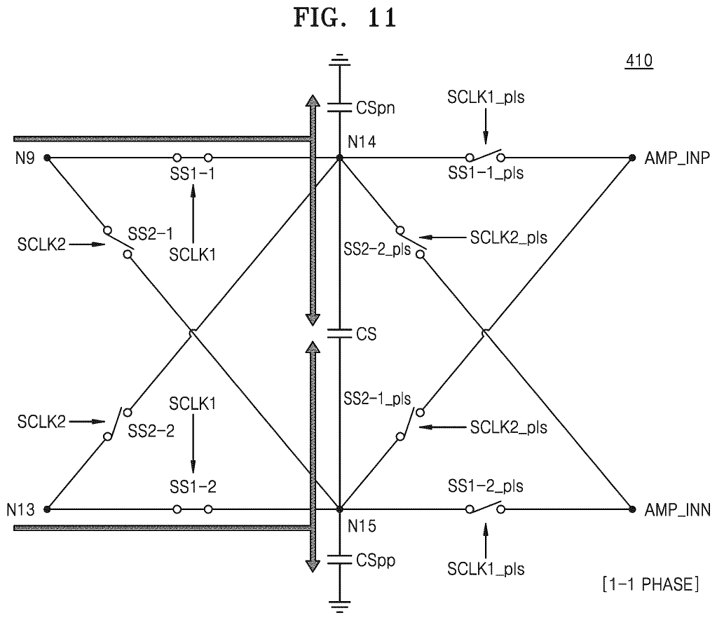

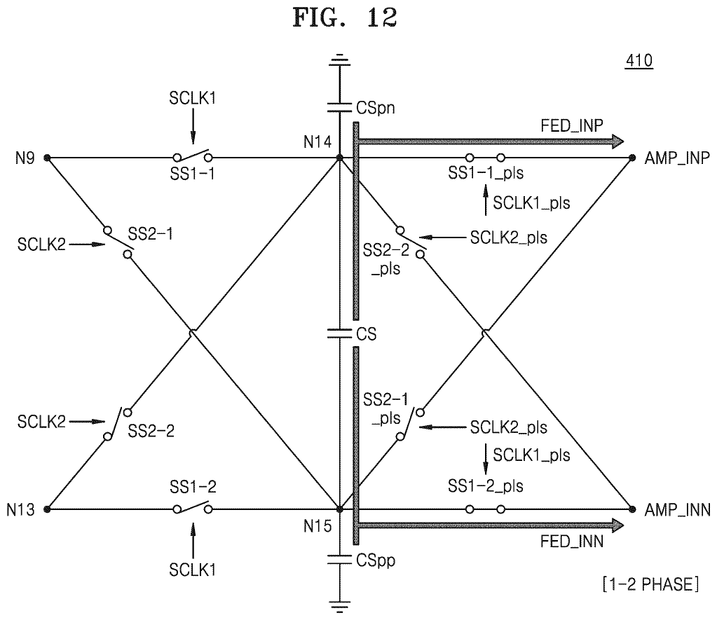

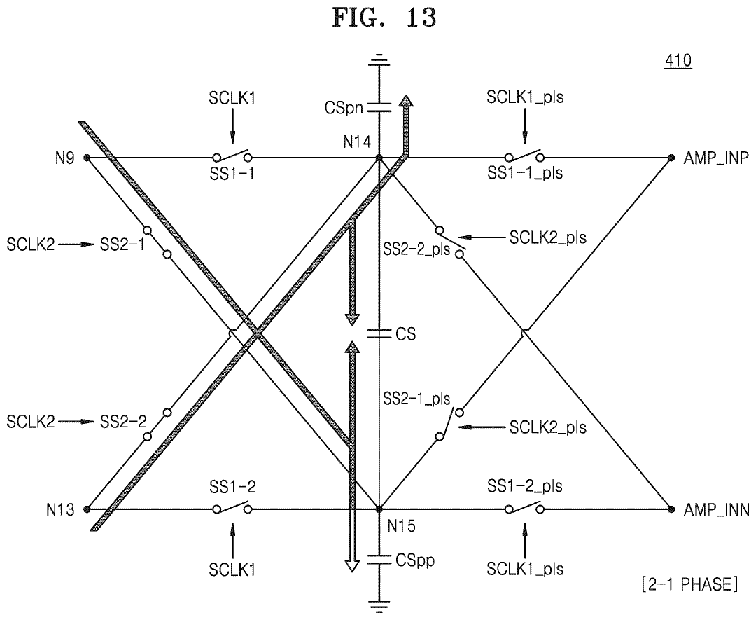

FIG. 8 is a diagram illustrating a third stage circuit according to an embodiment. FIG. 9 is a diagram showing an equivalent circuit of a third stage circuit according to an embodiment. FIG. 10 is a timing diagram showing sample clock signals SCLK1 and SLCK2 and sample clock pulse signals SCLK1_pls and SCLK2_pls. FIG. 11 is a diagram showing an operation of a cross sampling circuit of a 1^{st}-1 phase. FIG. 12 is a diagram showing an operation of a cross sampling circuit of a 1^{st}-2 phase. FIG. 13 is a diagram showing an operation of a cross sampling circuit of a 2^{nd}-1 phase. FIG. 14 is a diagram showing an operation of a cross sampling circuit of a 2^{nd}-2 phase.

Referring to FIG. 8, a third stage circuit 400 may be implemented as a cross sampling circuit 410.

The cross sampling circuit 410 may receive the first low-pass filter output signal LPF FILTER_OUTN and the second low-pass filter output signal LPF FILTER_OUTP and output a first feedback input signal FED_INP corresponding to the first low-pass filter output signal LPF FILTER_OUTN and a second feedback input signal FED_INN corresponding to the second low-pass filter output signal LPF FILTER_OUTP.

The cross sampling circuit 410 may include the 1^{st}-3 resistance path 110-3 and the 2^{nd}-3 resistance path 120-3.

Referring to FIG. 8, the cross sampling circuit 410 may output the first feedback input signal FED_INP to the node AMP_INP through the 1^{st}-3 resistance path 110-3, and the cross sampling circuit 410 may output the second feedback input signal FED_INN to the node AMP_INN through the 2^{nd}-3 resistance path 120-3.

The cross sampling circuit 410 may include a shared capacitor 420. In an embodiment, the shared capacitor 420 connects the 1^{st}-3 resistance path 110-3 to the 2^{nd}-3 resistance path 120-3. The shared capacitor 420 may correspond to the capacitor CS to be described with reference to FIGS. 9 to 14.

According to an embodiment, the third stage circuit 400 includes the capacitor CS, and thus the third stage circuit 400 (or the cross sampling circuit 410) may reduce mismatch between a resistance of the first resistance path 110 and a resistance of the second resistance path 120. Accordingly, unintended DC offset may be removed from the output signal.

The cross sampling circuit 410 may sample a low filter output signal by using different resistance paths for respective phases (e.g., a first phase or a second phase). That is, the cross sampling circuit 410 may output a feedback input signal by cross sampling the low filter output signal.

Here, the first phase may include a 1^{st}-1 phase and a 1^{st}-2 phase, and the second phase may include a 2^{nd}-1 phase and a 2^{nd}-2 phase.

The first and second phases will be described separately based on different resistance paths. It is noted that the 1^{st}-1 phase (or the 2^{nd}-1 phase) is a sampling phase in which a sampling operation is performed, and the 1^{st}-2 phase (or the 1^{st}-2 phase) is an output phase in which a sampled signal is output.

The cross sampling circuit 410 alternately samples (i.e., cross samples) the corresponding low filter output signal by using two parasitic capacitors for respective phases (e.g., the first phase or the second phase), thereby averaging the mismatch between resistance of the first resistance path 110 and resistance of the second resistance path 120 caused by the parasitic capacitors. Here, averaging may mean reducing an influence of parasitic capacitors by spreading the influence of parasitic capacitors over several cycles.

FIG. 9 is a diagram showing an equivalent circuit of the cross sampling circuit 410 according to an embodiment.

Referring to FIG. 9, in an embodiment, the cross sampling circuit 410 includes a plurality of sample switches SS1-1, SS1-1_pls, SS1-2, SS1-2_pls, SS2-1, SS2-1_pls, SS2-2, and SS1-2_pls and the shared capacitor 420.

The plurality of sample switches SS1-1, SS1-1_pls, SS1-2, SS1-2_pls, SS2-1, SS2-1_pls, SS2-2, and SS1-2_pls may be turned on or off based on sample clock signals SCLK1 and SCLK2 and sample clock pulse signals SCLK1_pls and SCLK2_pls. In this case, parasitic capacitance may be generated when the plurality of sample switches SS1-1, SS1-1_pls, SS1-2, SS1-2_pls, SS2-1, SS2-1_pls, SS2-2, and SS1-2_pls are turned on or off. Referring to FIG. 9, the parasitic capacitors CSpn and CSpp corresponding to the parasitic capacitance described above is provided.

Referring to FIGS. 7 and 9, a sample switch SS1-1 may be connected between the node N9 and a node N14. The sample switch SS1-1 may be turned on or off based on a first sample clock signal SCLK1. The sample switch SS1-2 may be connected between the node N13 and a node N15. The sample switch SS1-2 may be turned on or off based on the first sample clock signal SCLK1.

Referring to FIG. 9, the sample switch SS1-1_pls may be connected between the node N14 and the node AMP_INP. The sample switch SS1-1_pls may be turned on or off based on a first sample clock pulse signal SCLK1_pls. The sample switch SS1-2_pls may be connected between the node N15 and the node AMP_INN. The sample switch SS1-2_pls may be turned on or off based on a first sample clock pulse signal SCLK1_pls.

Referring to FIGS. 7 and 9, the sample switch SS2-1 may be connected between the node N9 and a node N15. The sample switch SS2-1 may be turned on or off based on a second sample clock signal SCLK2. The sample switch SS2-2 may be connected between the node N13 and the node N14. The sample switch SS2-2 may be turned on or off based on the second sample clock signal SCLK2.

Referring to FIG. 9, the sample switch SS2-1_pls may be connected between the node N15 and the node AMP_INP. The sample switch SS2-1_pls may be turned on or off based on a second sample clock pulse signal SCLK2_pls. The sample switch SS2-2_pls may be connected between the node N14 and the node AMP_INN. The sample switch SS2-2_pls may be turned on or off based on a second sample clock pulse signal SCLK2_pls.

A parasitic capacitor CSpn may be connected between the node N14 and a ground voltage line. A parasitic capacitor CSpp may be connected between the node N15 and the ground voltage line.

The capacitor CS may be connected between the node N14 and the node N15.

Hereinafter, an operation of the cross sampling circuit 410 in four phases 1-1 PHASE, 1-2 PHASE, 2-1 PHASE, and 2-2 PHASE (e.g., time periods) will be described in detail with reference to FIGS. 10 to 14.

In FIG. 10, it is assumed that when a logic level of the sample clock signals SCLK1 and SCLK2 is HIGH, a corresponding sample switch is turned on, that when a logic level of the sample clock signals SCLK1 and SCLK2 is LOW, a corresponding switch is turned off, that when a logic level of the sample clock pulse signals SCLK1_pls and SCLK2_pls is HIGH, a corresponding sample switch is turned on, and that when a logic level of the sample clock pulse signals SCLK1_pls and SCLK2_pls is LOW, a corresponding switch is turned off.

First, referring to FIGS. 10 and 11, an operation of the cross sampling circuit 410 in a 1^{st}-1 phase 1-1 PHASE will be described in detail.

Referring to FIGS. 10 and 11, in the 1^{st}-1 phase 1-1 PHASE, the sample switch SS1-1 and the sample switch SS1-2 are turned on in response to the first sample clock signal SCLK1.

Referring to FIGS. 10 and 11, the sample switch SS1-1_pls and the sample switch SS1-2_pls are turned off in response to the first sample clock pulse signal SCLK1_pls. The sample switch SS2-1 and the sample switch SS2-2 are turned off in response to the second sample clock signal SCLK2. The sample switch SS2-1_pls and the sample switch SS2-2_pls are turned off in response to the second sample clock pulse signal SCLK2_pls.

Accordingly, the first low-pass filter output signal LPF FILTER_OUTN applied to the node N9 may be sampled from the capacitor CS and the parasitic capacitor CSpn. That is, the capacitor CS and the parasitic capacitor CSpn may store an instantaneous voltage level of the first low-pass filter output signal LPF FILTER_OUTN of the 1^{st}-1 phase 1-1 PHASE. Here, the instantaneous voltage level of the first low-pass filter output signal LPF FILTER_OUTN may be divided and stored in each of the capacitor CS and the parasitic capacitor CSpn. For example, the voltage across each of the capacitors CS and CSpn may be the instantaneous voltage level times (a capacitance of the corresponding capacitor/total capacitance of CS and CSpn).

Similarly, the second low-pass filter output signal LPF FILTER_OUTP applied to the node N13 may be sampled from the capacitor CS and the parasitic capacitor CSpp. That is, the capacitor CS and the parasitic capacitor CSpp may store an instantaneous voltage level of the second low-pass filter output signal LPF FILTER_OUTP of the 1^{st}-1 phase 1-1 PHASE. Here, the instantaneous voltage level of the second low-pass filter output signal LPF FILTER_OUTP may be divided and stored in each of the capacitor CS and the parasitic capacitor CSpp.

Referring to FIGS. 10 and 12, an operation of the cross sampling circuit 410 in a 1^{st}-2 phase 1-2 PHASE will be described in detail.

Referring to FIG. 10, the 1^{st}-2 phase 1-2 PHASE may include a certain time interval after the first sample clock signal SCLK1 transitions from logic high HIGH to logic low LOW, a time interval during which the first sample clock pulse signal SCLK1_pls is logic high HIGH, and a certain time interval after the first sample clock pulse signal SCLK1_pls transitions from logic high HIGH to logic low LOW. Here, the certain time interval after transition described above may be a transient time interval for preparing for a next operation.

Referring to FIGS. 10 and 12, in the 1^{st}-2 phase 1-2 PHASE, the sample switch SS1-1_pls and the sample switch SS1-2_pls may be turned on in response to the first sample clock pulse signal SCLK1_pls. Here, the first sample clock pulse signal SCLK1_pls may be logic high HIGH.

Referring to FIGS. 10 and 12, the sample switch SS1-1 and the sample switch SS1-2 are turned off in response to the first sample clock signal SCLK1. The sample switch SS2-1 and the sample switch SS2-2 are turned off in response to the second sample clock signal SCLK2. The sample switch SS2-1_pls and the sample switch SS2-2_pls may be turned off in response to the second sample clock pulse signal SCLK2_pls.

Accordingly, the first feedback input signal FED_INP may be output to the node AMP_INP based on a voltage level stored in the capacitor CS and the parasitic capacitor CSpn. Here, the voltage level stored in the capacitor CS and the parasitic capacitor CSpn may correspond to the instantaneous voltage level of the first low-pass filter output signal LPF FILTER_OUTN of a phase sampled from the 1^{st}-1 phase 1-1 PHASE.

Similarly, the second feedback input signal FED_INN may be output to the node AMP_INP based on the voltage level stored in the capacitor CS and the parasitic capacitor CSpp. Here, the voltage level stored in the capacitor CS and the parasitic capacitor CSpp may correspond to the instantaneous voltage level of the second low-pass filter output signal LPF FILTER_OUTP of a phase sampled from the 1^{st}-1 phase 1-1 PHASE.

Referring to FIGS. 10 and 13, an operation of the cross sampling circuit 410 in a 2^{nd}-1 phase 2-1 PHASE will be described in detail.

Referring to FIGS. 10 and 13, in the 2^{nd}-1 phase 2-1 PHASE, the sample switch SS2-1 and the sample switch SS2-2 are turned on in response to the second sample clock signal SCLK2.

Referring to FIGS. 10 and 13, the sample switch SS1-1 and the sample switch SS1-2 are turned off in response to the first sample clock signal SCLK1. The sample switch SS1-1_pls and the sample switch SS1-2_pls are turned off in response to the first sample clock pulse signal SCLK1_pls. The sample switch SS2-1_pls and the sample switch SS2-2_pls are turned off in response to the second sample clock pulse signal SCLK2_pls.

Accordingly, the first low-pass filter output signal LPF FILTER_OUTN applied to the node N9 may be sampled from the capacitor CS and the parasitic capacitor CSpp. That is, the capacitor CS and the parasitic capacitor CSpp may store an instantaneous voltage level of the first low-pass filter output signal LPF FILTER_OUTN of the 2^{nd}-1 phase 2-1 PHASE. Here, the instantaneous voltage level of the first low-pass filter output signal LPF FILTER_OUTN may be divided and stored in each of the capacitor CS and the parasitic capacitor CSpp.

Similarly, the second low-pass filter output signal LPF FILTER_OUTP applied to the node N13 may be sampled from the capacitor CS and the parasitic capacitor CSpn. That is, the capacitor CS and the parasitic capacitor CSpn may store an instantaneous voltage level of the second low-pass filter output signal LPF FILTER_OUTP of the 2^{nd}-1 phase 2-1 PHASE. Here, the instantaneous voltage level of the second low-pass filter output signal LPF FILTER_OUTP may be divided and stored in each of the capacitor CS and the parasitic capacitor CSpn.

Referring to FIGS. 10 and 14, an operation of the cross sampling circuit 410 in a 2^{nd}-2 phase 2-2 PHASE will be described in detail.

Referring to FIG. 14, the 2^{nd}-2 phase 2-2 PHASE may include a certain time interval after the second sample clock signal SCLK2 transitions from logic high HIGH to logic low LOW, a time interval during which the second sample clock pulse signal SCLK2_pls is logic high HIGH, and a certain time interval after the second sample clock pulse signal SCLK2_pls transitions from logic high HIGH to logic low LOW. Here, the certain time interval after transition described above may be a transient time interval for preparing for a next operation.

Referring to FIGS. 10 and 14, in the 2^{nd}-2 phase 2-2 PHASE, the sample switch SS2-1_pls and the sample switch SS2-2_pls are turned on in response to the second sample clock pulse signal SCLK2_pls. Here, the second sample clock pulse signal SCLK2_pls may be logic high HIGH.

Referring to FIGS. 10 and 14, the sample switch SS1-1 and the sample switch SS1-2 are turned off in response to the first sample clock signal SCLK1. The sample switch SS1-1_pls and the sample switch SS1-2_pls are turned off in response to the first sample clock pulse signal SCLK1_pls. The sample switch SS2-1 and the sample switch SS2-2 are turned off in response to the second sample clock signal SCLK2.

Accordingly, the first feedback input signal FED_INP may be output to the node AMP_INP based on a voltage level stored in the capacitor CS and the parasitic capacitor CSpp. Here, the voltage level stored in the capacitor CS and the parasitic capacitor CSpp may correspond to the instantaneous voltage level of the first low-pass filter output signal LPF FILTER_OUTN of a phase sampled from the 2^{nd}-1 phase 2-1 PHASE.

Similarly, the second feedback input signal FED_INN may be output to the node AMP_INP based on the voltage level stored in the capacitor CS and the parasitic capacitor CSpn. Here, the voltage level stored in the capacitor CS and the parasitic capacitor CSpn may correspond to the instantaneous voltage level of the second low-pass filter output signal LPF FILTER_OUTP of a phase sampled from the 2^{nd}-1 phase 2-1 PHASE.

That is, according to an embodiment, the third stage circuit 400 (or the cross sampling circuit 410) may reduce mismatch between resistance of the first resistance path 110 and resistance of the second resistance path 120 by connecting the 1^{st}-3 resistance path 110-3 to the 2^{nd}-3 resistance path 120-3 with the capacitor CS. Accordingly, an unintended DC offset may be removed from the output signal.

According to an embodiment, in the first phase, the cross sampling circuit 410 samples the first low-pass filter output signal LPF FILTER_OUTN based on the parasitic capacitor CSpn and samples the second low-pass filter output signal LPF FILTER_OUTP based on the parasitic capacitor CSpp. In the second phase, the cross sampling circuit 410 may sample the first low-pass filter output signal LPF FILTER_OUTN based on the parasitic capacitor CSpp and sample the second low-pass filter output signal LPF FILTER_OUTP based on the parasitic capacitor CSpn. That is, the cross sampling circuit 410 alternately samples (i.e., cross samples) the corresponding low filter output signal by using two parasitic capacitors for respective phases (e.g., the first phase or the second phase), thereby averaging the mismatch between resistance of the first resistance path 110 and resistance of the second resistance path 120 caused by the parasitic capacitors. Here, averaging may mean reducing an influence of parasitic capacitors by spreading the influence of parasitic capacitors over several cycles.

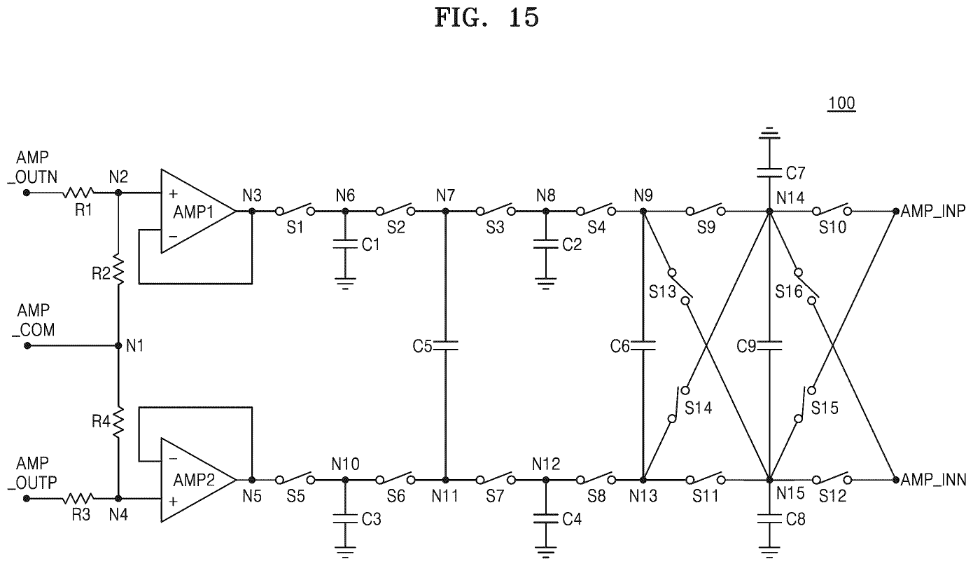

FIG. 15 is a diagram showing an equivalent circuit of a resistance circuit according to an embodiment. FIG. 15 is a diagram showing an equivalent circuit of the resistance circuit 100 including all equivalent circuits of the first stage circuit 200 described with reference to FIG. 4, the second stage circuit 300 described with reference to FIG. 7, and the third stage circuit 400 described with reference to FIG. 9. Repeated descriptions described with reference to FIGS. 2 to 14 may be omitted.

In an embodiment, the resistance circuit 100 includes resistors R1 to R4, operational amplifiers AMP1 and AMP2, switches S1 to S16, and capacitors C1 to C9.

The first resistor R1, the second resistor R2, the third resistor R3, and the fourth resistor R4 of FIG. 15 may correspond to the resistor R1, the resistor R2, the resistor R3, and the resistor R4 described with reference to FIG. 4, respectively. The first operational amplifier AMP1 and the second operational amplifier AMP2 of FIG. 15 may correspond to the operational amplifier AMP1 and the operational amplifier AMP2 described with reference to FIG. 4, respectively.

The first switch S1, the second switch S2, the third switch S3, the fourth switch S4, the fifth switch S5, the sixth switch S6, the seventh switch S7, and the eighth switch S8 of FIG. 15 may correspond to the switch S1-1, the switch S1-1b, the switch S2-1, the switch S2-1b, the switch S1-2, the switch S1-2b, the switch S2-2, and the switch S2-2b described with reference to FIG. 7, respectively. The first capacitor C1, the second capacitor C2, the third capacitor C3, and the fourth capacitor C4 of FIG. 15 may correspond to the capacitor Cf1n, the capacitor Cf2n, the capacitor Cf1p, and the capacitor Cf2p described with reference to FIG. 7, respectively.

The ninth switch S9, the tenth switch S10, the eleventh switch S11, the twelfth switch S12, the thirteenth switch S13, the fourteenth switch S14, the fifteenth switch S15, and the sixteenth switch S16 may correspond to the sample switch SS1-1, the sample switch SS1-1_pls, the sample switch SS1-2, the sample switch SS1-2_pls, the sample switch SS2-1, the sample switch SS2-2, the sample switch SS2-1_pls, and the sample switch SS2-2_pls described with reference to FIGS. 9 to 14, respectively. The seventh capacitor C7, the eighth capacitor C8, and the ninth capacitor C9 of FIG. 15 may correspond to the parasitic capacitor CSpn, the parasitic capacitor CSpp, and the capacitor CS described with reference FIGS. 9 to 14, respectively.

Referring to FIG. 1 and FIG. 15, the first resistor R1 may be connected between the node AMP_OUTN connecting the filter capacitor 30 to the inverting output terminal, and a second node N2. The second resistor R2 may be connected between the first node N1 connected to an output common mode signal line and the second node N2. The third resistor R3 may be connected between the node AMP_OUTP connecting the filter capacitor 30 to the non-inverting output terminal, and the fourth node N4. The fourth resistor R4 may be connected between the first node N1 and the fourth node N4. The first operational amplifier AMP1 may be connected between the second node N2 and the third node N3, the non-inverting input terminal of the first operational amplifier AMP1 may be connected to the second node N2, and the inverting input terminal of the first operational amplifier AMP1 may be connected to an output terminal of the first operational amplifier AMP1 at the third node N3. The second operational amplifier AMP2 may be connected between the fourth node N4 and the fifth node N5, the non-inverting input terminal of the second operational amplifier AMP2 may be connected to the fourth node N4, and the inverting input terminal of the second operational amplifier AMP2 may be connected to the output terminal of the second operational amplifier AMP2 at the fifth node N5. The first switch S1 may be connected between the third node N3 and the sixth node N6. The first capacitor C1 may be connected between the sixth node N6 and a ground voltage line. The second switch S2 may be connected between the sixth node N6 and the seventh node N7. The third switch S3 may be connected between the seventh node N7 and the eighth node N8. The second capacitor C2 may be connected between the eighth node N8 and the ground voltage line. The fourth switch S4 may be connected between the eighth node N8 and the ninth node N9. The fifth switch S5 may be connected between the fifth node N5 and the tenth node N10. The third capacitor C3 may be connected between the tenth node N10 and the ground voltage line. The sixth switch S6 may be connected between the tenth node N10 and the eleventh node N11. The seventh switch S7 may be connected between the eleventh node N11 and the twelfth node N12. The fourth capacitor C4 may be connected between the twelfth node N12 and the ground voltage line. The eighth switch S8 may be connected between the twelfth node N12 and the thirteenth node N13. The fifth capacitor C5 may be connected between the seventh node N7 and the eleventh node N11. The sixth capacitor C6 may be connected between the ninth node N9 and the thirteenth node N13. The ninth switch S9 may be connected between the ninth node N9 and the fourteenth node N14. The seventh capacitor C7 may be connected between the fourteenth node N14 and the ground voltage line. The tenth switch S10 may be connected between the node AMP_INP connecting the filter capacitor 30 to the non-inverting input terminal, and the fourteenth node N14. The eleventh switch S11 may be connected between the thirteenth node N13 and the fifteenth node N15. The eighth capacitor C8 may be connected between the fifteenth node N15 and the ground voltage line. The twelfth switch S12 may be connected between the node AMP_INN connecting the filter capacitor 30 to the inverting input terminal, and the fifteenth node N15. The thirteenth switch S13 may be connected between the ninth node N9 and the fifteenth node N15. The fourteenth switch S14 may be connected between the thirteenth node N13 and the fourteenth node N14. The fifteenth switch S15 may be connected between the node AMP_INP connecting the filter capacitor 30 to the non-inverting input terminal, and the fifteenth node N15. The sixteenth switch S16 may be connected between the node AMP_INN connecting the filter capacitor 30 to the inverting input terminal, and the fourteenth node N14. The ninth capacitor C9 may be connected between the fourteenth node N14 and the fifteenth node N15.

The at least one capacitor 130 described with reference to FIG. 1 may correspond to at least one of the fifth capacitor C5, the sixth capacitor C6, and the ninth capacitor C9 of FIG. 15.

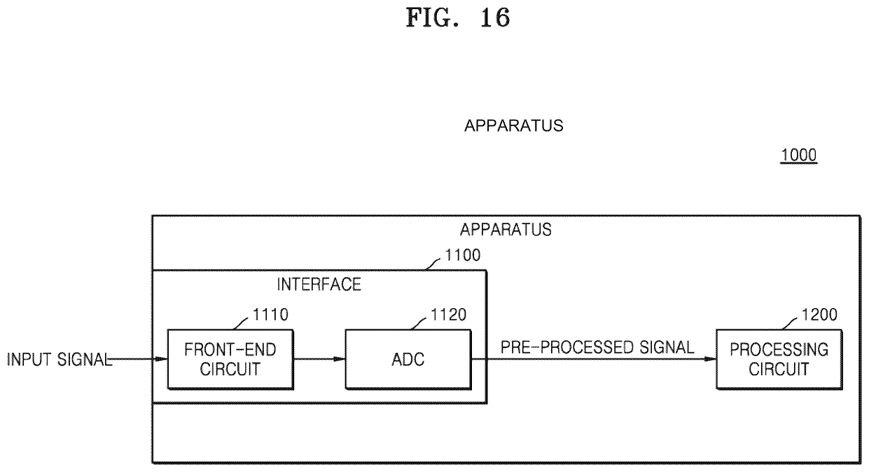

FIG. 16 is a block diagram illustrating an apparatus according to an embodiment. In some embodiments, the high pass filter 1 (or resistance circuit 100) described above with reference to the drawings may be used to pre-process a signal received from an apparatus 1000. For example, the high pass filter 1 (or resistance circuit 100) described above may be provided in a front-end circuit 1110 illustrated in FIG. 16.

The apparatus 1000 may be any signal processing device. The apparatus 1000 may process signals having a low frequency (e.g., less than a reference frequency) or DC components. For example, the apparatus 1000 may process a signal having a low frequency such as at least one of frequency components between about 0 Hz and about 1 MHz.

For example, the apparatus 1000 may be an acoustic device that converts between electric signals and sound signals, such as a Micro-Electro-Mechanical System microphone (MEMS MIC), a condenser microphone, or a speaker, or a component provided in the acoustic device. For example, the apparatus 1000 may be an electrocardiogram (ECG) processing device, a temperature information processing device, a distance information processing device, a parking assistance system (PAS), a dust information processing device, or a pressure processing device.

Referring to FIG. 16, the apparatus 1000 may include an interface 1100 and a processing circuit 1200. Here, the interface 1100 may also be referred to as a sensor interface.

Referring to FIG. 16, the interface 1100 may receive an input signal INPUT SIGNAL, preprocess the input signal INPUT SIGNAL to generate a preprocessed signal PRE-PROCESSED SIGNAL, and provide the preprocessed signal PRE-PROCESSED SIGNAL to the processing circuit 1200.

Referring to FIG. 16, the interface 1100 may include the front-end circuit 1110 and an analog-to-digital converter 1120. The interface 1100 may include any sensor, and the sensor may receive the input signal INPUT SIGNAL. Here, the sensor may be implemented as various sensors such as a MEMS MIC, a condenser microphone, an ECG sensor, a temperature sensor, a construction sensor, a distance sensor, a dust sensor, or a pressure sensor.

The front-end circuit 1110 may perform preprocessing on the input signal INPUT SIGNAL and provide a preprocessed signal in analog form to the analog-to-digital converter 1120.

In an embodiment, the front-end circuit 1110 may include the high pass filter 1 (or the resistance circuit 100) described above. Despite a low frequency of the input signal INPUT SIGNAL, the resistance circuit 100 may provide high resistance to the front-end circuit 1110.

The analog-to-digital converter 1120 may receive a preprocessed signal in analog form and provide the preprocessed signal PRE-PROCESSED SIGNAL to the processing circuit 1200. Here, the analog-to-digital converter 1120 may be implemented as an oversampling ADC, a sigma-delta ADC or an incremental sigma-delta ADC.

The processing circuit 1200 may receive the preprocessed signal PRE-PROCESSED SIGNAL and perform subsequent processing operations based on the preprocessed signal PRE-PROCESSED SIGNAL.

As described above, the embodiments have been disclosed in the drawings and specifications. Although certain terms have been used to describe embodiments in this specification, the terms have been used simply to explain the technical idea of the inventive concept and are not intended to limit the meaning or the scope of the inventive concept set forth in the claims. Therefore, those skilled in the art will understand that various modifications and equivalent other embodiments are possible therefrom.

What is claimed is:

1. A high pass filter comprising:
an amplifier comprising an input terminal and an output terminal;
a filter capacitor connected between the input terminal and the output terminal; and
a resistance circuit connected between the input terminal and the output terminal,
wherein the resistance circuit includes:
a first stage circuit including an attenuating circuit configured to receive an amplifier feedback output signal applied from a node connected to the output terminal of the amplifier and to the filter capacitor, and output an attenuated signal by attenuating a voltage level of the amplifier feedback output signal;
a second stage circuit configured to receive the attenuated signal and perform a low filtering operation on the attenuated signal to output a low filter output signal; and
a third stage circuit configured to receive the low filter output signal and perform a cross sampling operation on the low filter output signal to output a feedback input signal to a node connected to the input terminal of the amplifier and to the filter capacitor.

2. The high pass filter of claim 1, wherein the first stage circuit further includes a buffer configured to buffer the attenuated signal and output the buffered attenuated signal to the second stage circuit.

3. The high pass filter of claim 1, wherein the second stage circuit includes a first resistance path, a second resistance path and a capacitor connecting the first resistance path to the second resistance path.

4. The high pass filter of claim 1, wherein the second stage circuit includes a first switched capacitor circuit, a first low pass filter (LPF) capacitor, a second switched capacitor circuit, and a second LPF capacitor circuit.

5. The high pass filter of claim 4, wherein the second stage circuit outputs the low filter output signal by performing a first-order low filtering operation on the attenuated signal by using the first switched capacitor circuit and the first LPF capacitor to generate a result and performing a second-order low filtering operation on the result by using the second switched capacitor circuit and the second LPF capacitor.

6. The high pass filter of claim 1, wherein the third stage circuit samples a first low filter output signal based on a first parasitic capacitor and samples a second low filter output signal based on a second parasitic capacitor in a first phase, and samples a first low filter output signal based on the second parasitic capacitor and samples a second low filter output signal based on the first parasitic capacitor in a second phase.

7. The high pass filter of claim 1, wherein the third stage circuit includes a first resistance path, a second resistance path and a capacitor connecting the first resistance path to the second resistance path.

8. The high pass filter of claim 7, wherein the third stage circuit samples the low filter output signal based on a capacitor connecting the first resistance path to the second resistance path.

9. An acoustic device including a high pass filter, the high pass filter comprising:
an amplifier comprising an input terminal and an output terminal;
a filter capacitor connected between the input terminal and the output terminal; and
a resistance circuit connected between the input terminal and the output terminal,
wherein the resistance circuit includes:
a first stage circuit including an attenuating circuit configured to receive an amplifier feedback output signal applied from a node connected to the output terminal of the amplifier and to the filter capacitor, and output an attenuated signal by attenuating a voltage level of the amplifier feedback output signal;
a second stage circuit configured to receive the attenuated signal and perform a low filtering operation on the attenuated signal to output a low filter output signal; and
a third stage circuit configured to receive the low filter output signal and perform a cross sampling operation on the low filter output signal to output a feedback input signal to a node connected to the input terminal of the amplifier and to the filter capacitor.

10. The acoustic device of claim 9, wherein the first stage circuit further includes a buffer configured to buffer the attenuated signal and output the buffered attenuated signal to the second stage circuit.

11. The acoustic device of claim 9, wherein the second stage circuit includes a first resistance path, a second resistance path and a capacitor connecting the first resistance path to the second resistance path.

12. The acoustic device of claim 9, wherein the second stage circuit includes a first switched capacitor circuit, a first low pass filter (LPF) capacitor, a second switched capacitor circuit, and a second LPF capacitor circuit.

13. The acoustic device of claim 12, wherein the second stage circuit outputs the low filter output signal by performing a first-order low filtering operation on the attenuated signal by using the first switched capacitor circuit and the first LPF capacitor to generate a result and performing a second-order low filtering operation on the by using the second switched capacitor circuit and the second LPF capacitor.

14. The acoustic device of claim 9, wherein the third stage circuit samples a first low filter output signal based on a first parasitic capacitor and samples a second low filter output signal based on a second parasitic capacitor in a first phase, and samples a first low filter output signal based on the second parasitic capacitor and samples a second low filter output signal based on the first parasitic capacitor in a second phase.

15. The acoustic device of claim 9, wherein the third stage circuit includes a first resistance path, a second resistance path and a capacitor connecting the first resistance path to the second resistance path.

16. The acoustic device of claim 15, wherein the third stage circuit samples the low filter output signal based on a capacitor connecting the first resistance path to the second resistance path.

17. A high pass filter comprising:
an amplifier comprising an input terminal including a non-inverting input terminal and an inverting input terminal, and an output terminal including an inverting output terminal and a non-inverting output terminal;
a filter capacitor connected between the input terminal and the output terminal; and
a resistance circuit connected between the input terminal and the output terminal,
wherein the resistance circuit includes:
a first resistor connected between a node connecting the filter capacitor to the inverting output terminal, and a second node;
a second resistor connected between a first node connected to an output common mode signal line, and the second node;
a third resistor connected between a node connecting the filter capacitor to the non-inverting output terminal, and a fourth node;
a fourth resistor connected between the first node and the fourth node;
a first operational amplifier connected between the second node and a third node, a non-inverting input terminal of the first operational amplifier being connected to the second node, and an inverting input terminal of the first operational amplifier being connected to an output terminal of the first operational amplifier at the third node;
a second operational amplifier connected between the fourth node and a fifth node, a non-inverting input terminal of the second operational amplifier being connected to the fourth node, and an inverting input terminal of the second operational amplifier being connected to an output terminal of the second operational amplifier at the fifth node;
a first switch connected between the third node and a sixth node;
a first capacitor connected between the sixth node and a ground voltage line;
a second switch connected between the sixth node and a seventh node;
a third switch connected between the seventh node and an eighth node;
a second capacitor connected between the eighth node and the ground voltage line;
a fourth switch connected between the eighth node and a ninth node;
a fifth switch connected between the fifth node and a tenth node;
a third capacitor connected between the tenth node and the ground voltage line;
a sixth switch connected between the tenth node and an eleventh node;
a seventh switch connected between the eleventh node and a twelfth node;
a fourth capacitor connected between the twelfth node and the ground voltage line;
an eighth switch connected between the twelfth node and a thirteenth node;
a fifth capacitor connected between the seventh node and the eleventh node;
a sixth capacitor connected between the ninth node and the thirteenth node;
a ninth switch connected between the ninth node and a fourteenth node;
a seventh capacitor connected between the fourteenth node and the ground voltage line;
a tenth switch connected between a node connecting the filter capacitor to the non-inverting input terminal, and the fourteenth node;
an eleventh switch connected between the thirteenth node and a fifteenth node;
an eighth capacitor connected between the fifteenth node and the ground voltage line;
a twelfth switch connected between a node connecting the filter capacitor to the inverting input terminal, and the fifteenth node;
a thirteenth switch connected between the ninth node and the fifteenth node;
a fourteenth switch connected between the thirteenth node and the fourteenth node;
a fifteenth switch connected between a node connecting the filter capacitor to the non-inverting input terminal, and the fifteenth node;
a sixteenth switch connected between a node connecting the filter capacitor to the inverting input terminal, and the fourteenth node; and
a ninth capacitor connected between the fourteenth node and the fifteenth node.

18. The high pass filter of claim 17, wherein the resistance circuit samples a first low filter output signal based on the seventh capacitor and samples a second low filter output signal based on the eighth capacitor in a first phase, and samples a first low filter output signal based on the eighth capacitor and samples a second low filter output signal based on the seventh capacitor in a second phase.

19. The high pass filter of claim 17, wherein the resistance circuit samples a low filter output signal based on the ninth capacitor.

20. The high pass filter of claim 17, wherein the ninth switch and the eleventh switch are turned on in response to a sample clock signal in a sampling phase, and
the tenth switch and the twelfth switch are turned on in response to a sample clock pulse signal in an output phase.
